(19) United States
(12) Patent Application Publication
(10) Pub. No.: US 2013/0075722 A1
(43) Pub. Date: Mar. 28, 2013

(54) SEMICONDUCTOR DEVICE

(71) Applicants: Shunpei YAMAZAKI, Setagaya (JP); Atsuo ISOBE, Isehara (JP); Yutaka OKAZAKI, Isehara (JP); Takehisa HATANO, Atsugi (JP); Sachiaki TEZUKA, Atsugi (JP); Suguru HONDO, Atsugi (JP); Toshihiko SAITO, Atsugi (JP)

(72) Inventors: Shunpei YAMAZAKI, Setagaya (JP); Atsuo ISOBE, Isehara (JP); Yutaka OKAZAKI, Isehara (JP); Takehisa HATANO, Atsugi (JP); Sachiaki TEZUKA, Atsugi (JP); Suguru HONDO, Atsugi (JP); Toshihiko SAITO, Atsugi (JP)

(73) Assignee: SEMICONDUCTOR ENERGY LABORATORY CO., LTD., Atsugi-shi (JP)

(21) Appl. No.: 13/613,192

(22) Filed: Sep. 13, 2012

(30) Foreign Application Priority Data
Sep. 23, 2011 (JP) 2011-208232

(51) Int. Cl. H01L 29/786

(52) U.S. Cl. 257/43; 257/E29.296

(57) ABSTRACT

A highly reliable structure for high-speed response and high-speed driving of a semiconductor device, in which on-state characteristics of a transistor are increased is provided. In the coplanar transistor, an oxide semiconductor layer, a source and drain electrode layers including a stack of a first conductive layer and a second conductive layer, a gate insulating layer, and a gate electrode layer are sequentially stacked in this order. The gate electrode layer is overlapped with the first conductive layer with the gate insulating layer provided therebetween, and is not overlapped with the second conductive layer with the gate insulating layer provided therebetween.

### TECHNICAL FIELD

The present invention relates to a semiconductor device and a method for manufacturing the semiconductor device.

In this specification, the semiconductor device means any device which can function by utilizing semiconductor characteristics, and an electrooptic device, a semiconductor circuit, and an electronic device are all included in the category of the semiconductor device.

### BACKGROUND ART

Attention has been focused on a technique for forming a transistor using a semiconductor thin film formed over a substrate having an insulating surface (the transistor is also referred to as a thin film transistor (TFT)). The transistor has been widely applied to electronic devices such as an integrated circuit (IC) or an image display device (display device). A silicon-based semiconductor material is widely known as a material for a semiconductor thin film applicable to the transistor. As another material for the same, an oxide semiconductor has been attracting attention.

For example, disclosure has been made of a coplanar-type, top-gate transistor whose active layer is formed using an amorphous oxide containing indium (In), gallium (Ga), and zinc (Zn) (see Patent Document 1).

### REFERENCE

Patent Document 1: Japanese Published Patent Application No. 2006-165528

### DISCLOSURE OF INVENTION

A structure in which a gate electrode is surely overlapped with a channel formation region in an active layer is preferable in order to increase on-state characteristics (e.g., on-state current or field-effect mobility) of a transistor to enable high-speed response and high-speed driving of a semiconductor device. According to the structure, a gate voltage can be surely applied to the channel formation region between a source and a drain of the transistor, whereby the resistance between the source and the drain can be reduced.

In a coplanar transistor in which a source electrode and a drain electrode are provided with a space therebetween with a gate electrode provided between the source electrode and the drain electrode, there exists a space between the gate electrode and each of the source electrode and the drain electrode when seen in the top plane or the cross section. That space behaves as a resistor in operating the transistor.

Thus, in the case of using a silicon-based semiconductor material, an impurity is added to a semiconductor region in that space to reduce the resistance of that space, whereby the gate electrode is surely overlapped with a channel formation region in an active layer to increase on-state characteristics. On the other hand, in the case of using an oxide semiconductor as a semiconductor material, a structure in which respective end portions of the source electrode and the drain electrode are aligned with or overlapped with an end portion of the gate electrode is preferable to reduce the resistance of that space.

However, in such a structure of the transistor in which respective end portions of the source electrode and the drain electrode are aligned with or overlapped with an end portion of the gate electrode when seen in the top plane or the cross section, there is a problem of a short circuit between the gate electrode and the source electrode or the drain electrode. This short circuit between the electrodes is attributed to coverage failure to the source electrode, the drain electrode, and the oxide semiconductor layer with a gate insulating layer. In particular, such coverage failure is likely to become obvious as the gate insulating layer is thinned by miniaturization of the transistor.

Coverage failure or the like particularly of the gate insulating layer provided over the source electrode, the drain electrode, and the oxide semiconductor layer is more likely to cause a short circuit particularly in a region which is in contact with a part of the oxide semiconductor layer and is a channel formation region. In many cases, the source electrode and the drain electrode are provided to be thicker than the gate insulating layer in order to increase the on-state characteristics. Therefore, when the gate insulating layer is formed to be thin, the coverage failure further increases over edge portions of the source electrode and the drain electrode as the thickness of each of the source electrode and the drain electrode is increased; consequently, a short circuit is more likely to occur between the electrodes, leading to a reduction in reliability.

One object of one embodiment of the present invention is to provide a highly reliable structure for high-speed response and high-speed driving of a semiconductor device, in which on-state characteristics of a transistor are increased.

One embodiment of the present invention is a semiconductor device in which an oxide semiconductor layer, a source and drain electrode layers including a stack of a first conductive layer and a second conductive layer, a gate insulating layer, and a gate electrode layer are sequentially stacked in a transistor. The gate electrode layer is overlapped with the first conductive layer with the gate insulating layer provided therebetween, and is not overlapped with the second conductive layer with the gate insulating layer provided therebetween.

One embodiment of the present invention is a semiconductor device in which an oxide semiconductor layer is provided over a substrate having an insulating surface, a first conductive layer is provided partly over the oxide semiconductor layer, a second conductive layer is provided partly over the first conductive layer, a gate insulating layer is provided over the oxide semiconductor layer, the first conductive layer, and the second conductive layer, and a gate electrode layer is provided over the oxide semiconductor layer with the gate insulating layer provided therebetween. The gate electrode layer is overlapped with the first conductive layer with the gate insulating layer provided therebetween, and is not overlapped with the second conductive layer with the gate insulating layer provided therebetween.

One embodiment of the present invention is a semiconductor device in which an oxide semiconductor layer is provided over a substrate having an insulating surface, a first conductive layer is provided partly over the oxide semiconductor layer, a second conductive layer is provided partly over the first conductive layer, an insulating layer is provided over the second conductive layer, a gate insulating layer is provided over the oxide semiconductor layer, the first conductive layer, the second conductive layer, and the insulating layer, and a gate electrode layer is provided over the oxide semiconductor layer with the gate insulating layer provided therebetween. The gate electrode layer is overlapped with the first conductive layer with the gate insulating layer provided therebetween, and is not overlapped with the second conductive layer with the gate insulating layer provided therebetween.

One embodiment of the present invention is a semiconductor device in which an oxide semiconductor layer is provided over a substrate having an insulating surface, a first conductive layer is provided partly over the oxide semiconductor layer, an insulating layer is provided partly over the first conductive layer, a second conductive layer is provided partly over the insulating layer and is in contact with the first conductive layer in an opening in the insulating layer, a gate insulating layer is provided over the oxide semiconductor layer, the first conductive layer, the second conductive layer, and the insulating layer, and a gate electrode layer is provided over the oxide semiconductor layer with the gate insulating layer provided therebetween. The gate electrode layer is overlapped with the first conductive layer with the gate insulating layer provided therebetween, and is not overlapped with the second conductive layer with the gate insulating layer provided therebetween.

One embodiment of the present invention is a semiconductor device in which an oxide semiconductor layer is provided over an insulating layer partly having an embedded conductive layer over a substrate having an insulating surface, a first conductive layer is provided partly over the oxide semiconductor layer, a second conductive layer is provided partly over the first conductive layer, a gate insulating layer is provided over the oxide semiconductor layer, the first conductive layer, and the second conductive layer, and a gate electrode layer is provided over the oxide semiconductor layer with the gate insulating layer provided therebetween. The gate electrode layer is overlapped with the first conductive layer with the gate insulating layer provided therebetween, and is not overlapped with the second conductive layer with the gate insulating layer provided therebetween.

In one embodiment of the present invention, it is preferable that the insulating layer partly having the embedded conductive layer be provided such that the embedded conductive layer is in contact with the first conductive layer in an opening in the oxide semiconductor layer in the semiconductor device.

In one embodiment of the present invention, it is preferable that the insulating layer partly having the embedded conductive layer have an embedded oxide semiconductor layer over the embedded conductive layer in the semiconductor device.

In one embodiment of the present invention, it is preferable that the insulating layer partly having the embedded conductive layer and the embedded oxide semiconductor layer be provided such that the embedded oxide semiconductor layer be in contact with the first conductive layer in the opening in the oxide semiconductor layer in the semiconductor device.

In one embodiment of the present invention, it is preferable that the thickness of the first conductive layer be greater than or equal to 5 nm and less than or equal to 20 nm in the semiconductor device.

In one embodiment of the present invention, it is preferable that the thickness of the gate insulating layer be greater than or equal to 10 nm and less than or equal to 20 nm in the semiconductor device.

In one embodiment of the present invention, it is preferable that the thickness of the oxide semiconductor layer be greater than or equal to 5 nm and less than or equal to 20 nm in the semiconductor device.

In one embodiment of the present invention, it is preferable that a buffer layer be provided over the substrate having the insulating surface in the semiconductor device.

In one embodiment of the present invention, it is preferable that the buffer layer be a layer containing an oxide of at least one element selected from aluminum, gallium, zirconium, hafnium, and rare-earth elements in the semiconductor device.

In one embodiment of the present invention, it is preferable that the oxide semiconductor layer have crystals whose c-axes are aligned in the semiconductor device.

To realize a semiconductor device with higher performance, according to one embodiment of the present invention, a highly reliable structure for high-speed response and high-speed driving of a semiconductor device can be provided, in which on-state characteristics (e.g., on-state current or field-effect mobility) of a transistor are increased.

### BRIEF DESCRIPTION OF DRAWINGS

In the accompanying drawings:

FIG. 1 is a diagram illustrating one embodiment of a semiconductor device;

FIGS. 2A to 2E are diagrams illustrating one embodiment of a manufacturing method of a semiconductor device;

FIGS. 3A and 3B are diagrams each illustrating one embodiment of a semiconductor device;

FIG. 4 is a diagram illustrating one embodiment of a semiconductor device;

FIGS. 5A and 5B are diagrams each illustrating one embodiment of a semiconductor device;

FIGS. 6A and 6B are diagrams each illustrating one embodiment of a semiconductor device;

FIGS. 7A to 7C are diagrams illustrating one embodiment of a semiconductor device;

FIGS. 8A to 8C are a cross-sectional diagram, a plane view, and a circuit diagram illustrating one embodiment of a semiconductor device;

FIGS. 9A and 9B are a circuit diagram and a perspective view illustrating one embodiment of a semiconductor device;

FIG. 10A is a plane view illustrating one embodiment of a semiconductor device, and FIGS. 10B and 10C are cross-sectional diagrams illustrating the same;

FIGS. 11A and 11B are circuit diagrams each illustrating one embodiment of a semiconductor device;

FIG. 12 is a block diagram illustrating one embodiment of a semiconductor device;

FIG. 13 is a block diagram illustrating one embodiment of a semiconductor device;

FIG. 14 is a block diagram illustrating one embodiment of a semiconductor device; and

FIGS. 15A to 15E are diagrams each illustrating one embodiment of an electronic device using a semiconductor device.

### BEST MODE FOR CARRYING OUT THE INVENTION

Hereinafter, embodiments of the present invention are described with reference to the accompanying drawings. However, the present invention can be carried out in many different modes, and those skilled in the art could appreciate that a variety of modifications can be made to the embodiment and details of the present invention without departing from the spirit and scope of the present invention. Therefore, the present invention should not be interpreted as being limited to the description in the following embodiments.

Note that the size, the thickness of a layer, and a region of each structure illustrated in the drawings and the like in the embodiments are exaggerated for simplicity in some cases. Therefore, embodiments of the present invention are not confined to such scales.

Further, ordinal numbers such as first, second, third, . . . Nth (N is a natural number) in this specification are used in order to avoid confusion among components, and thus give no numeral limitation.

### Embodiment 1

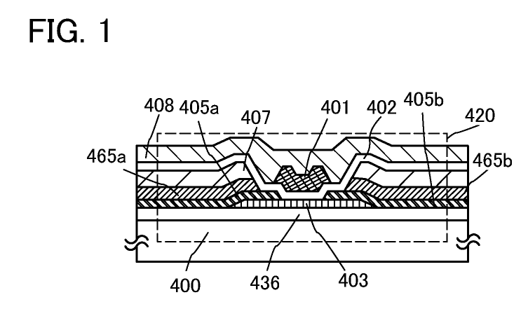

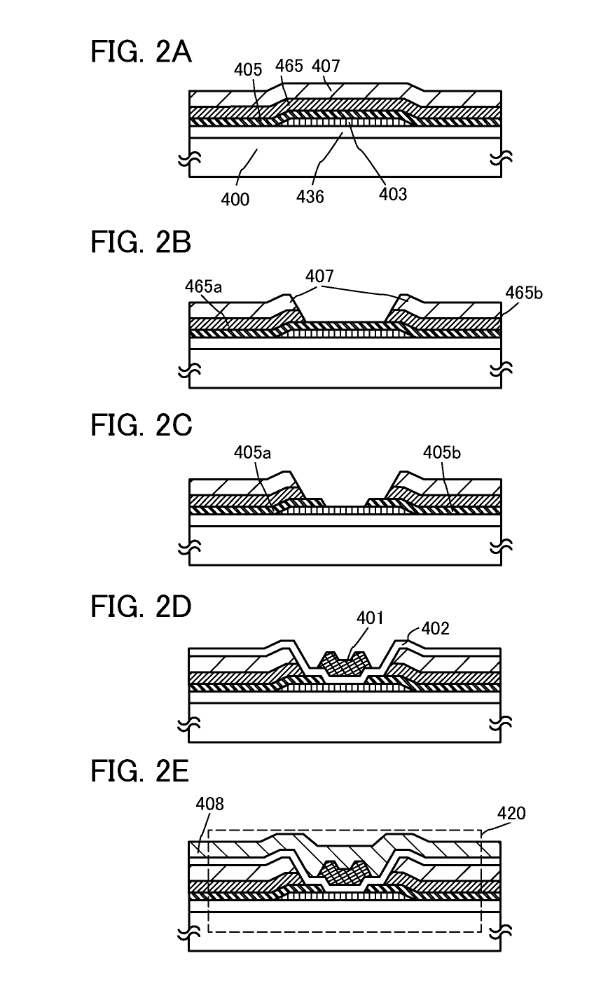

In this embodiment, a semiconductor device and a manufacturing method thereof according to one embodiment of the present invention are described using FIG. 1, FIGS. 2A to 2E, FIGS. 3A and 3B, and FIG. 4.

FIG. 1 is a cross-sectional diagram of a transistor 420 which is an example of a structure of a semiconductor device. The transistor 420 has a single-gate structure in which one channel formation region is formed, but instead may have a double-gate structure in which two channel formation regions are formed, or a triple-gate structure in which three channel formation regions are formed.

The transistor 420 includes, over a substrate 400 having an insulating surface, a buffer layer 436, an oxide semiconductor layer 403, first conductive layers 405a and 405b, second conductive layers 465a and 465b, an insulating layer 407, a gate insulating layer 402, a gate electrode layer 401, and an interlayer insulating layer 408 (see FIG. 1).

In the structure shown in FIG. 1 described in this embodiment, the first conductive layers 405a and 405b, which function as a source and drain electrodes of the transistor 420, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 1 described in this embodiment, the second conductive layers 465a and 465b, which function as a source and drain electrodes of the transistor 420, are not overlapped with the gate electrode layer 401 with the gate insulating layer 402 provided therebetween, in respective regions of the second conductive layers 465a and 465b which are overlapped with the oxide semiconductor layer 403.

In the structure shown in FIG. 1 described in this embodiment, respective end portions of the first conductive layers 405a and 405b, which function as the source and drain electrodes of the transistor, can be overlapped with an end portion of the gate electrode layer 401 which functions as a gate electrode of the transistor. Accordingly, on-state characteristics (e.g., on-state current or field-effect mobility) of the transistor can be increased, enabling high-speed response and high-speed driving of the semiconductor device.

Further, in the structure shown in FIG. 1 described in this embodiment, the first conductive layers 405a and 405b, which function as the source and drain electrodes of the transistor, can be formed to be thin. By forming the first conductive layers 405a and 405b to be thin, the level of a step in the surface on which the gate insulating layer 402 is formed particularly in the vicinity of a channel formation region of the oxide semiconductor layer 403 can be low. Accordingly, the gate insulating layer 402 can be formed with good coverage. A reduction in coverage failure leads to a reduction in occurrence of a short circuit between electrodes, increasing the reliability. In addition, since the respective end portions of the second conductive layers 465a and 465b, which function as the source and drain electrodes of the transistor, can be prevented from being overlapped with the end portion of the gate electrode layer 401, which functions as the gate electrode, in the structure shown in FIG. 1 described in this embodiment, an increase in the thickness of the second conductive layers 465a and 465b as compared to the thickness of the first conductive layers 405a and 405b does not lead to generation of a short circuit between electrodes. Therefore, by increasing the thickness of the second conductive layers 465a and 465b, the source-drain current can be increased without causing a short circuit between electrodes.

Further, in the structure shown in FIG. 1 described in this embodiment, the first conductive layers 405a and 405b can be formed to be thin, whereby the time taken to process for forming the first conductive layers 405a and 405b by a step such as etching can be shortened. Accordingly, the oxide semiconductor layer 403 can be less damaged by processing to form the first conductive layers 405a and 405b by a step such as etching. Consequently, the reliability can be increased.

Further, according to the structure shown in FIG. 1 described in this embodiment, a coplanar structure in which the gate insulating layer 402 is thin can be provided, and the oxide semiconductor layer 403 can be provided to be thin over the buffer layer 436 whose flatness is increased. Reduction in the thicknesses of the gate insulating layer 402 and the oxide semiconductor layer 403 not only leads to an increase in on-state characteristics but also enables the transistor to operate as a fully-depleted transistor. Such an operation of the transistor as the fully-depleted transistor enables high integration, high-speed driving, and low power consumption.

Further, in the structure shown in FIG. 1 described in this embodiment, the second conductive layers 465a and 465b and the insulating layer 407 are overlapped with each other and their side surfaces can be tapered by a process such as etching. Therefore, favorable coverage can be obtained even when the thickness of the second conductive layers 465a and 465b is increased.

As described above, in the structure shown in FIG. 1 described in this embodiment, the source electrode and the drain electrode of the transistor can be overlapped with the gate electrode without decreasing the source-drain current of the transistor, whereby on-state characteristics can be increased. Further, in the structure shown in FIG. 1 described in this embodiment, the coverage failure with the gate insulating layer can be decreased, which enables the oxide semiconductor layer and the gate insulating layer to be thin. In that case, the transistor in which an oxide semiconductor is used for a channel formation region can be miniaturized, which is preferable.

Next, an example of a method for manufacturing the transistor 420 shown in FIG. 1 is described using FIGS. 2A to 2E.

First, the buffer layer 436 is formed over the substrate 400 having an insulating surface. The buffer layer 436 is a layer for suppressing reaction between the oxide semiconductor layer 403 formed over the buffer layer 436 and the substrate 400 having an insulating surface.

There is no particular limitation on a substrate that can be used as the substrate 400 having an insulating surface as long as it has heat resistance enough to withstand heat treatment performed later. For example, a glass substrate of barium borosilicate glass, aluminoborosilicate glass, or the like, a ceramic substrate, a quartz substrate, or a sapphire substrate can be used. A single crystal semiconductor substrate or a polycrystalline semiconductor substrate of silicon, carbon silicon, or the like; a compound semiconductor substrate of silicon germanium or the like; an SOI substrate; or the like can also be used as the substrate 400, or the substrate provided with a semiconductor element can also be used as the substrate 400.

The buffer layer 436, which is in contact with the oxide semiconductor layer 403, is preferably formed using an oxide of the same kind(s) of constituent(s) as the oxide semiconductor layer 403. Specifically, it is preferable that the buffer layer 436 be a layer containing an oxide of at least one element selected from constituent elements of the oxide semiconductor layer 403 such as aluminum (Al), gallium (Ga), zirconium (Zr), and hafnium (Hf), and rare-earth elements belonging in the same group as aluminum, gallium, and the like. Among these elements, an oxide of aluminum, gallium, or a rare-earth element, which is a Group III element, is more preferably used. As the rare-earth element, scandium (Sc), yttrium (Y), cerium (Ce), samarium (Sm), or gadolinium (Gd) is preferably used. Such a material is compatible with the oxide semiconductor layer 403, and the use of such a material for the buffer layer 436 enables a state of the interface between the oxide semiconductor layer 403 and the buffer layer 436 to be favorable. Further, the crystallinity of the oxide semiconductor layer 403 can be improved.

Since the oxide semiconductor layer 403 is used as an active layer of the transistor 420, it is requisite that the energy gap of the buffer layer 436 be larger than that of the oxide semiconductor layer 403; it is preferable that the buffer layer 436 have electrical insulating properties.

The buffer layer 436 is either a single layer or a stacked layer.

There is no particular limitation on the forming method of the buffer layer 436; a plasma-enhanced CVD method, a sputtering method, or the like can be employed.

A planarization treatment may be performed on the surface of the buffer layer 436. The planarization treatment may be, but not particularly limited to, a polishing treatment (such as chemical mechanical polishing (CMP)), a dry etching treatment, or a plasma treatment.

Next, the oxide semiconductor layer 403 is formed over the buffer layer 436.

In the formation of the oxide semiconductor layer 403, the concentration of hydrogen in the oxide semiconductor layer 403 is preferably reduced as much as possible. For example, in the case where the oxide semiconductor layer 403 is formed by a sputtering method, in order to reduce the hydrogen concentration, a high-purity rare gas (typically argon), high-purity oxygen, or a high-purity mixed gas of a rare gas and oxygen, from which impurities such as hydrogen, water, a hydroxyl group, and hydride have been removed, is supplied as an atmosphere gas into a treatment chamber of a sputtering apparatus as appropriate.

Further, it is preferable that the oxide semiconductor layer 403 and the buffer layer 436 be formed continuously without exposure to the atmosphere. By continuously forming the oxide semiconductor layer 403 and the buffer layer 436 without exposure to the atmosphere, adsorption of impurities such as hydrogen and moisture to the interface between the oxide semiconductor layer 403 and the buffer layer 436 can be prevented.

Further, to reduce the impurity concentration in the oxide semiconductor layer 403, it is also effective to form the oxide semiconductor layer 403 while the substrate 400 is kept at high temperature. The temperature at which the substrate 400 is heated may be higher than or equal to 150° C. and lower than or equal to 450° C.; it is preferable that the substrate temperature be higher than or equal to 200° C. and lower than or equal to 350° C. Further, by forming the oxide semiconductor layer 403 while heating the substrate 400 at a high temperature, a crystalline oxide semiconductor layer can be formed as the oxide semiconductor layer 403.

An oxide semiconductor used for the oxide semiconductor layer 403 preferably contains at least indium (In) or zinc (Zn). In particular, In and Zn are preferably contained. As a stabilizer for reducing variation in electrical characteristics of the transistor using the oxide semiconductor, gallium (Ga) is preferably further contained. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

As another stabilizer, one or plural kinds of lanthanoid selected from lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

For example, as the oxide semiconductor, any of the following can be used: an indium oxide; a tin oxide; a zinc oxide; a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide; and a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide.

Note that, for example, the In—Ga—Zn-based oxide means an oxide containing In, Ga, and Zn, and there is no limitation on the composition ratio of In, Ga, and Zn. The In—Ga—Zn-based oxide may further contain a metal element other than In, Ga, and Zn.

The oxide semiconductor layer 403 is preferably deposited under a condition such that much oxygen is contained (for example, by a sputtering method in an atmosphere where the proportion of oxygen is 100%) so as to be a film containing much oxygen (preferably containing excessive oxygen as compared to the stoichiometric composition ratio of the oxide semiconductor in a crystalline state).

It is preferable to use a high-purity gas from which impurities such as hydrogen, water, a hydroxyl group, or hydride have been removed, as a sputtering gas used for forming the oxide semiconductor layer 403.

Note that a highly-purified oxide semiconductor (purified oxide semiconductor) obtained by reduction of impurities such as moisture or hydrogen which serves as an electron donor (donor) and by reduction of oxygen vacancies is an intrinsic (i-type) semiconductor or a substantially i-type semiconductor. Therefore, a transistor using the oxide semiconductor has a feature of very small off-state current. Furthermore, the band gap of the oxide semiconductor is 2 eV or more, preferably 2.5 eV or more, further preferably 3 eV or more. Use of such an oxide semiconductor layer which is highly purified by reduction of impurities such as moisture or hydrogen and by reduction of oxygen vacancies leads to a reduction in the off-state current of a transistor.

Unless otherwise specified, in the case of an n-channel transistor, the off-state current in this specification is a current which flows between a source terminal and a drain terminal at a gate potential of less than or equal to zero with respect to the potential of the source terminal in the state where the potential of the drain terminal is greater than that of any of the source terminal and the gate potential.

The oxide semiconductor can have a single crystal state, a polycrystalline (also referred to as polycrystal) state, an amorphous state, or the like. In particular, it is preferable that the oxide semiconductor used for the oxide semiconductor layer 403 be a mixed layer containing a crystal region and an amorphous region and be a crystalline oxide semiconductor.

In a crystalline oxide semiconductor, defects in the bulk can be more reduced, and the mobility can be more increased by increasing its surface flatness. To increase the surface flatness, the oxide semiconductor is preferably formed on a flat surface; specifically, the oxide semiconductor is preferably formed on a surface with an average surface roughness (Rₐ) of less than or equal to 1 nm, further preferably less than or equal to 0.3 nm, still further preferably less than or equal to 0.1 nm.

The average surface roughness (Rₐ) is obtained by expanding, into three dimensions, arithmetic mean surface roughness that is defined by JIS B 0601:2001 (ISO4287:1997) so as to be able to apply to a curved surface, and can be expressed as an “average value of the absolute values of deviations from a reference surface to a designated surface” and is defined by the following formula:

$$Ra = \frac{1}{{S}_{0}} {\int }_{{y}_{2}}^{{y}_{1}} {\int }_{{x}_{2}}^{{x}_{1}} \vert f ( x , y ) - {Z}_{0} \vert d x d y \qquad [ FORMULA 1 ]$$

In the formula, the designated surface is a surface which is subjected to the roughness measurement, and is a quadrilateral region which is specified by 4 points represented by the coordinates (x₁, y₁, f(x₁, y₁)), (x₁, y₂, f(x₁, y₂)), (x₂, y₁, f(x₂, y₁)), and (x₂, y₂, f(x₂, y₂)), and S₀ represents the area of a rectangle which is obtained by projecting the designated surface on the x-y plane, and Z₀ represents the height of the reference surface (the average height of the designated surface). The average surface roughness (Rₐ) can be measured with an atomic force microscope (AFM).

The crystalline oxide semiconductor is preferably a c-axis aligned crystalline oxide semiconductor (CAAC-OS).

The CAAC-OS is neither complete single crystal nor complete amorphous. The CAAC-OS is an oxide semiconductor with a crystal-amorphous mixed phase structure where a crystal portion(s) with a size of several nanometers to several tens of nanometers is/are included in an amorphous phase. With the transmission electron microscope (TEM), a boundary between the amorphous portion and the crystal portion in the CAAC-OS is not clear. Further, a grain boundary is not found in the CAAC-OS. Since the CAAC-OS does not include a grain boundary, a reduction in electron mobility due to a grain boundary is less likely to occur.

In the crystal portion(s) included in the CAAC-OS, the c-axes are aligned in a direction perpendicular to a surface where the CAAC-OS is formed or a surface of the CAAC-OS, triangular or hexagonal atomic arrangement which is seen from the direction perpendicular to the a-b plane is formed, and metal atoms are arranged in a layered manner or metal atoms and oxygen atoms are arranged in a layered manner when seen from the direction perpendicular to the c-axis. Note that, among the crystal portions, the direction of any of the a-axis and the b-axis of the crystal portion may differ.

Note that the proportions of the amorphous portion and the crystal portion in the CAAC-OS are not necessarily uniform. For example, in the case where crystal growth proceeds from a surface side of the CAAC-OS, in some cases, the proportion of the crystal portion tends to be high in the vicinity of the surface of the CAAC-OS and the proportion of the amorphous portion tends to be high in the vicinity of the surface where the CAAC-OS is formed.

Since the c-axis of the crystal portion included in the CAAC-OS is aligned in the direction perpendicular to the surface where the CAAC-OS is formed or the surface of the CAAC-OS, the directions of the c-axes of the crystal portions may differ depending on the shape of the CAAC-OS (the cross-sectional shape of the surface where the CAAC-OS is formed or the cross-sectional shape of the surface of the CAAC-OS). The direction of c-axis of the crystal portion is the direction perpendicular to the surface where the CAAC-OS is formed or the surface of the CAAC-OS. The crystal portion is formed after film deposition or is formed by performing a treatment for crystallization such as a heat treatment after film deposition.

Use of the CAAC-OS leads to a reduction in fluctuation in electrical characteristics of the transistor due to irradiation with visible light or ultraviolet light, whereby a highly reliable transistor can be provided.

As an example of the above-described oxide semiconductor layer 403, an In—Ga—Zn-based oxide deposited by a sputtering method using a target containing In (indium), Ga (gallium), and Zn (zinc) can be given. The oxide semiconductor layer 403 can be formed to have a thickness greater than or equal to 1 nm and less than or equal to 30 nm (preferably greater than or equal to 5 nm and less than or equal to 20 nm).

The CAAC-OS is formed by, for example, a sputtering method using an oxide semiconductor sputtering target which is a polycrystal. When ions collide with the sputtering target, a crystal region included in the sputtering target may be cleaved along the a-b plane, so that a flat-plate-like or pellet-like sputtered particle having a plane parallel to the a-b plane may be separated from the sputtering target. In that case, the flat-plate-like sputtered particles reach the substrate while maintaining their crystal states, whereby the CAAC-OS can be formed.

In the case where the In—Ga—Zn-based oxide is deposited by a sputtering method, it is preferable to use an In—Ga—Zn-based oxide target having an atomic ratio of In:Ga:Zn=1:1:1, 4:2:3, 3:1:2, 1:1:2, 2:1:3, or 3:1:4. When the oxide semiconductor layer is formed using an In—Ga—Zn-based oxide target having one of those atomic ratios, a polycrystal or CAAC-OS is more likely to be formed. In addition, the filling factor of the target containing In, Ga, and Zn is greater than or equal to 90% and less than or equal to 100%, preferably greater than or equal to 95% and less than 100%. Use of the target with a high filling factor enables the oxide semiconductor layer to be dense.

The oxide semiconductor layer may be formed as follows: the substrate is held in a treatment chamber with pressure reduced, residual moisture in the treatment chamber is removed, a sputtering gas from which hydrogen and moisture are removed is introduced, and the above-described target is used. At that time, the substrate temperature may be higher than or equal to 100° C. and lower than or equal to 600° C., preferably higher than or equal to 200° C. and lower than or equal to 400° C. By heating the substrate in forming the layer, the concentration of impurities in the oxide semiconductor layer can be reduced. In addition, damage by sputtering can be alleviated. To remove remaining moisture in the treatment chamber, an adsorption vacuum pump is preferably used. For example, a cryopump, an ion pump, or a titanium sublimation pump is preferably used. The evacuation unit may be a turbo pump provided with a cold trap. In the treatment chamber which is evacuated with the cryopump, for example, a hydrogen atom, a compound containing a hydrogen atom, such as water (H₂O) (preferably, also a compound containing a carbon atom), and the like are removed, whereby the impurity concentration in the oxide semiconductor layer formed in the treatment chamber can be reduced.

The oxide semiconductor layer formed by a sputtering method or the like, in some cases, contains a large amount of moisture or hydrogen (including a hydroxyl group) as impurities. Therefore, to reduce impurities such as moisture or hydrogen in the oxide semiconductor layer (dehydration or dehydrogenation), the oxide semiconductor layer is subjected to a heat treatment in a reduced-pressure atmosphere, an inert gas atmosphere of nitrogen, a rare gas, or the like, an oxygen gas atmosphere, or an ultra dry air atmosphere (the amount of moisture is 20 ppm (−55° C. by conversion into a dew point) or less, preferably 1 ppm or less, further preferably 10 ppb or less, according to the measurement with a dew point meter in a cavity ring down laser spectroscopy (CRDS) method).

The heat treatment performed on the oxide semiconductor layer can eliminate moisture or hydrogen in the oxide semiconductor layer. Specifically, the heat treatment may be performed at a temperature higher than or equal to 250° C. and lower than or equal to 750° C., preferably higher than or equal to 400° C. and lower than the strain point of the substrate. For example, the heat treatment may be performed at 500° C. for about 3 minutes to about 6 minutes. When an RTA method is used for the heat treatment, dehydration or dehydrogenation can be performed in a short time; therefore, the heat treatment can be performed even at a temperature higher than the strain point of a glass substrate.

The heat treatment to eliminate moisture or hydrogen in the oxide semiconductor layer can be performed anytime in the manufacturing process of the transistor 420 after formation of the oxide semiconductor layer 403 before formation of the interlayer insulating layer 408. Further, the heat treatment for the dehydration or dehydrogenation may be performed plural times, and may double as another heat treatment.

In some cases, the heat treatment makes oxygen released from the oxide semiconductor layer, so that an oxygen vacancy is formed in the oxide semiconductor layer. Therefore, it is preferable to use a gate insulating layer containing oxygen as the gate insulating layer which is formed later to be in contact with the oxide semiconductor layer. Then, a heat treatment is preferably performed thereon after formation of the gate insulating layer containing oxygen, so that oxygen is supplied from the gate insulating layer to the oxide semiconductor layer. With the above-described structure, oxygen vacancies that serve as donors can be reduced, so that the stoichiometric composition ratio of the oxide semiconductor of the oxide semiconductor layer can be satisfied. As a result, the oxide semiconductor layer can be made substantially i-type and variation in electrical characteristics of the transistor due to oxygen vacancies can be reduced, leading to an improvement of electrical characteristics.

The heat treatment for supplying oxygen to the semiconductor layer is performed in a nitrogen atmosphere, ultra-dry air, or a rare gas (e.g., argon or helium) atmosphere preferably at a temperature higher than or equal to 200° C. and lower than or equal to 400° C., for example, higher than or equal to 250° C. and lower than or equal to 350° C. The water content in the gas is preferably less than or equal to 20 ppm, further preferably less than or equal to 1 ppm, still further preferably less than or equal to 10 ppb.

Further or alternatively, oxygen (which includes at least one of an oxygen radical, an oxygen atom, and an oxygen ion) may be added to the oxide semiconductor layer having being subjected to the dehydration or dehydrogenation treatment, in order to supply oxygen to the oxide semiconductor layer.

Oxygen which is added to the dehydrated or dehydrogenated oxide semiconductor layer 403 to supply oxygen to the layer can highly purify the oxide semiconductor layer 403 and make the layer i-type (intrinsic). Fluctuation in electrical characteristics of the transistor having the highly-purified, i-type oxide semiconductor layer 403 is suppressed; the transistor is electrically stabilized.

As the method for adding oxygen, an ion implantation method, an ion doping method, a plasma immersion ion implantation method, a plasma treatment, or the like can be used.

The oxide semiconductor layer 403 can be formed by processing an oxide semiconductor layer into an island shape by a photolithography process.

For the etching of the oxide semiconductor layer 403, either or both of dry etching and wet etching can be used. As an etchant used for wet etching of the oxide semiconductor layer 403, a mixed solution of phosphoric acid, acetic acid, and nitric acid can be used, for example. Further, ITO07N (produced by KANTO CHEMICAL CO., INC.) may be used.

In FIG. 2A, the oxide semiconductor layer 403 has an island shape and an end portion thereof is tapered at a degree greater than or equal to 20° and less than or equal to 50°. If the end portion of the oxide semiconductor layer 403 is perpendicular to the bottom surface, oxygen is more likely to be released from the oxide semiconductor layer 403 to cause more oxygen vacancies; generation of oxygen vacancies can be suppressed by tapering the end portion. Such suppression of generation of oxygen vacancies can lead to suppression of generation of a leakage current (parasitic channel) of the transistor 420.

Next, a first conductive layer 405 which serves as a source and drain electrode layers (including a wiring formed of the same layer as the source and drain electrode layers) is formed over the oxide semiconductor layer 403 and the buffer layer 436.

The first conductive layer 405 is formed using a material that can withstand a heat treatment performed later. As the first conductive layer 405 used for the source and drain electrode layers, for example, a metal film containing an element selected from Al, Cr, Cu, Ta, Ti, Mo, and W, a metal nitride film containing any of the above elements as its component (e.g., a titanium nitride film, a molybdenum nitride film, or a tungsten nitride film), or the like can be used.

In the case where a metal film of Al, Cu, or the like is used for the first conductive layer 405, it is preferable that a film of a high-melting-point metal such as Ti, Mo, or W or a metal nitride film thereof (e.g., a titanium nitride film, a molybdenum nitride film, or a tungsten nitride film) be stacked over or/and below the metal film.

Further, the first conductive layer 405 used for the source and drain electrode layers may also be formed using a conductive metal oxide. As the conductive metal oxide, indium oxide (In₂O₃), tin oxide (SnO₂), zinc oxide (ZnO), indium oxide-tin oxide (In₂O₃—SnO₂; abbreviated to ITO), indium oxide-zinc oxide (In₂O₃—ZnO), or any of these metal oxide materials to which silicon oxide is added can be used.

It is preferable that the first conductive layer 405 be thinner than a second conductive layer 465 formed later. Specifically, it is preferable that the first conductive layer 405 be as thin as possible to prevent a coverage failure with the gate insulating layer 402 formed later; the first conductive layer 405 may be formed to have a thickness greater than or equal to 1 nm and less than or equal to 30 nm (preferably greater than or equal to 10 nm and less than or equal to 20 nm).

Next, the second conductive layer 465 which serves as a source and drain electrode layers (including a wiring formed of the same layer as the source and drain electrode layers) is formed over the first conductive layer 405.

The second conductive layer 465 is formed using a material which can withstand a heat treatment later. As the second conductive layer 465 used for the source and drain electrode layers, for example, a metal film containing an element selected from Al, Cr, Cu, Ta, Ti, Mo, and W, a metal nitride film containing any of the above elements as its component (e.g., a titanium nitride film, a molybdenum nitride film, or a tungsten nitride film), or the like can be used.

Further, a film of a high-melting-point metal such as Ti, Mo, or W or a metal nitride film thereof (e.g., a titanium nitride film, a molybdenum nitride film, or a tungsten nitride film) may be stacked over or/and below the metal film of Al, Cu, or the like.

Further, the second conductive layer 465 used for the source and drain electrode layers may also be formed using a conductive metal oxide. As the conductive metal oxide, indium oxide (In₂O₃), tin oxide (SnO₂), zinc oxide (ZnO), indium oxide-tin oxide (In₂O₃—SnO₂; abbreviated to ITO), indium oxide-zinc oxide (In₂O₃—ZnO), or any of these metal oxide materials to which silicon oxide is added can be used.

In the case where a single layer of a metal film of Al, Cu, or the like is used as the second conductive layer 465, it is preferable that a film of a high-melting-point metal such as Ti, Mo, or W or a metal nitride film thereof (e.g., a titanium nitride film, a molybdenum nitride film, or a tungsten nitride film) be used for the first conductive layer 405. With that structure, Al, Cu, or the like used for the second conductive layer 465 enables a reduction in wiring resistance, and an increase of resistance by oxidation of Al, Cu, or the like due to direct contact between the oxide semiconductor layer and Al, Cu, or the like can be reduced. Further, it is preferable that a material whose etching selectivity relative to the first conductive layer 405 in etching in a later step (step in FIG. 2B) is high be used for the second conductive layer 465.

It is preferable that the second conductive layer 465 be thicker than the first conductive layer 405. Specifically, the second conductive layer 465 can be formed to have any thickness as small as a thickness at which the wiring resistance of the second conductive layer 465 functioning as the source or drain electrode layer is not large.

Next, the insulating layer 407 is formed over the second conductive layer 465. The insulating layer 407 is not a requisite element, but is effective as a mask in processing the first conductive layer 405 and the second conductive layer 465 in a later step or as a protection layer to protect the upper surface of the source and drain electrodes.

The insulating layer 407 can be formed by a CVD method, a sputtering method, or the like. The insulating layer 407 is preferably formed so as to include a silicon oxide, a silicon nitride, a silicon oxynitride, a silicon nitride oxide, an aluminum oxide, a hafnium oxide, a tantalum oxide, or the like. The insulating layer 407 has either a single-layer structure or a stacked-layer structure. There are no particular limitations on the thickness of the insulating layer 407.

The foregoing is the description of the process to result in the state shown in FIG. 2A.

Next, by a photolithography process, a resist mask is formed over the insulating layer 407, and the second conductive layer 465 and the insulating layer 407 are partly subjected to an etching treatment, so that the second conductive layers 465a and 465b are formed, and then, the resist mask is removed. With the etching treatment, the second conductive layer 465 and the insulating layer 407 are each separated over the oxide semiconductor layer 403. The separated second conductive layers 465a and 465b function as the source electrode layer and the drain electrode layer of the transistor 420.

The foregoing is the description of the process to result in the state shown in FIG. 2B.

Next, by a photolithography process, a resist mask is formed over the first conductive layer 405, and an etching treatment is partly thereon, so that the first conductive layers 405a and 405b are formed, and then, the resist mask is removed. With the etching treatment, the first conductive layer 405 is separated over the oxide semiconductor layer 403. The separated first conductive layers 405a and 405b function as the source electrode layer and the drain electrode layer of the transistor 420.

The thickness of the first conductive layer 405 over the oxide semiconductor layer 403 can be made uniform by forming the first conductive layer 405 to be thinner than the second conductive layer 465. Also, by forming the first conductive layer 405 to be thin, the time taken to process the first conductive layer 405 by the etching treatment can be shortened. Accordingly, damage to the oxide semiconductor layer 403 in processing the first conductive layer 405 can be reduced. Accordingly, the reliability can be increased.

The foregoing is the description of the process to result in the state shown in FIG. 2C.

Next, the gate insulating layer 402 is formed to cover the oxide semiconductor layer 403, the first conductive layers 405a and 405b, the second conductive layers 465a and 465b, and the insulating layer 407.

The gate insulating layer 402 can be formed to have a thickness greater than or equal to 1 nm and less than or equal to 20 nm, preferably a thickness greater than or equal to 10 nm and less than or equal to 20 nm by a sputtering method, an MBE method, a CVD method, a pulse laser deposition method, an ALD method, or the like as appropriate. The gate insulating layer 402 may be formed using a sputtering apparatus which performs film deposition with surfaces of a plurality of substrates set substantially perpendicular to a surface of a sputtering target.

The gate insulating layer 402 can be formed using a silicon oxide film, a gallium oxide film, an aluminum oxide film, a silicon nitride film, a silicon oxynitride film, an aluminum oxynitride film, or a silicon nitride oxide film.

It is preferable that the gate insulating layer 402 include oxygen in a portion which is in contact with the oxide semiconductor layer 403. In particular, the gate insulating layer 402 preferably includes oxygen which exceeds at least the stoichiometric ratio in the layer (bulk); for example, in the case where silicon oxide is used for the gate insulating layer 402, the composition formula is SiO_{2+α} (α>0).

In this embodiment, silicon oxide of SiO_{2+α} (α>0) is used for the gate insulating layer 402. By using the silicon oxide for the gate insulating layer 402, oxygen can be supplied to the oxide semiconductor layer 403, leading to an increase in characteristics.

The gate insulating layer 402 can also be formed using a high-k material such as hafnium oxide, yttrium oxide, hafnium silicate (HfSiₓO_{y} (x>0, y>0)), hafnium silicate to which nitrogen is added (HfSiOₓN_{y} (x>0, y>0)), hafnium aluminate (HfAlₓO_{y} (x>0, y>0)), or lanthanum oxide, whereby the gate leakage current can be reduced. Further, the gate insulating layer 402 has either a single-layer structure or a stacked-layer structure.

Then, the gate electrode layer 401 is formed over the gate insulating layer 402 by a plasma-enhanced CVD method, a sputtering method, or the like.

The gate electrode layer 401 can be formed using a metal material such as molybdenum, titanium, tantalum, tungsten, aluminum, copper, chromium, neodymium, or scandium or an alloy material which contains any of these materials as its main component. Further or alternatively, a semiconductor film which is doped with an impurity element such as phosphorus and is typified by a polycrystalline silicon film, or a silicide film of nickel silicide or the like may be used as the gate electrode layer 401. The gate electrode layer 401 has either a single-layer structure or a stacked-layer structure.

The gate electrode layer 401 can also be formed using a conductive material such as an indium tin oxide, an indium oxide containing a tungsten oxide, an indium zinc oxide containing a tungsten oxide, an indium oxide containing a titanium oxide, an indium tin oxide containing a titanium oxide, an indium zinc oxide, or an indium tin oxide to which a silicon oxide is added. The gate electrode layer 401 can have a stacked-layer structure of the above conductive material and the above metal material.

As one layer of the gate electrode layer 401 which is in contact with the gate insulating layer 402, a metal oxide containing nitrogen, specifically, an In—Ga—Zn—O film containing nitrogen, an In—Sn—O film containing nitrogen, an In—Ga—O film containing nitrogen, an In—Zn—O film containing nitrogen, a Sn—O film containing nitrogen, an In—O film containing nitrogen, or a metal nitride (e.g., InN or SnN) film can be used. These films each have a work function of 5 eV or higher, preferably 5.5 eV or higher, which enables the threshold voltage of the electrical characteristics of the transistor to take a positive value when used for the gate electrode layer, so that a switching element of so-called normally-off type can be provided.

The foregoing is the description of the process to result in the state shown in FIG. 2D.

Next, the interlayer insulating layer 408 is formed over the gate insulating layer 402 and the gate electrode layer 401 (see FIG. 2E).

The interlayer insulating layer 408 can be formed by a plasma-enhanced CVD method, a sputtering method, an evaporation method, or the like. As the interlayer insulating layer 408, an inorganic insulating layer of a silicon oxide, a silicon oxynitride, an aluminum oxynitride, a gallium oxide, or the like can be typically used.

For the interlayer insulating layer 408, an aluminum oxide, a hafnium oxide, a magnesium oxide, a zirconium oxide, a lanthanum oxide, a barium oxide, or a metal nitride (e.g., an aluminum nitride film) can also be used.

The interlayer insulating layer 408 has either a single-layer structure or a stacked-layer structure; for example, a stack of a silicon oxide film and an aluminum oxide film can be used.

The interlayer insulating layer 408 is preferably formed by a method by which impurities such as water and hydrogen do not enter the interlayer insulating layer 408, such as a sputtering method. It is preferable that the interlayer insulating layer 408 be a film containing excessive oxygen because it can serve as an oxygen supply source to the oxide semiconductor layer 403 through the gate insulating layer 402 in contact with the oxide semiconductor layer 403.

In this embodiment, a 100-nm-thick silicon oxide film is formed as the interlayer insulating layer 408 by a sputtering method. The deposition of a silicon oxide film by a sputtering method can be performed in a rare gas (typically, argon) atmosphere, an oxygen atmosphere, or a mixed atmosphere of a rare gas and oxygen.

In order to remove moisture remaining in the deposition chamber of the interlayer insulating layer 408, in a manner similar to that of the deposition of the oxide semiconductor layer, an adsorption vacuum pump (e.g., a cryopump) is preferably used. By depositing the interlayer insulating layer 408 in the deposition chamber which is exhausted with a cryopump, the impurity concentration in the interlayer insulating layer 408 can be reduced. In addition, as an exhaustion unit for removing moisture remaining in the deposition chamber of the interlayer insulating layer 408, a turbo molecular pump provided with a cold trap may be used.

A high-purity gas from which impurities such as hydrogen, water, a hydroxyl group, and hydride have been removed is preferably used as a sputtering gas used for deposition of the interlayer insulating layer 408.

The aluminum oxide film which can be used as the interlayer insulating layer 408 provided over the oxide semiconductor layer 403 has a high shielding (blocking) effect of preventing penetration of both oxygen and impurities such as hydrogen and moisture.

Therefore, in and after the manufacturing process, the aluminum oxide film functions as a protective film for preventing entry of impurities such as hydrogen and moisture, which cause a change, into the oxide semiconductor layer 403 and release of oxygen, which is a main constituent material of the oxide semiconductor, from the oxide semiconductor layer 403.

Further, a planarization insulating film may be formed thereover in order to reduce surface roughness due to the transistor. As the planarization insulating film, an organic material such as polyimide, acrylic, or a benzocyclobutene-based resin can be used. Other than the organic material, it is also possible to use a low-dielectric constant material (low-k material) or the like. The planarization insulating film may also be formed by stacking a plurality of insulating films formed from these materials.

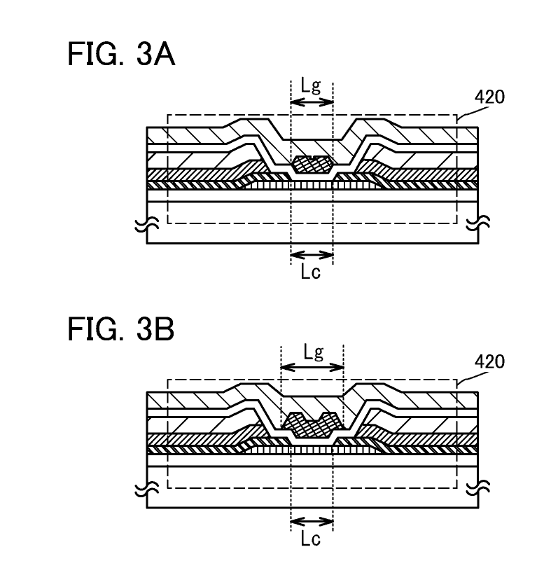

In the structure of the transistor described in this embodiment, a distance Lc between the first conductive layer 405a and the first conductive layer 405b which function as the source and drain electrodes is a channel length of the transistor 420. In the structure described in this embodiment, a length in the channel length direction Lg of the gate electrode layer 401 can be either equal to the channel length Lc as shown in FIG. 3A or greater than the channel length Lc as shown in FIG. 3B. That is, according to the structure of the transistor described in this embodiment, an end portion of the gate electrode layer 401, which functions as a gate electrode of the transistor, can be overlapped with an end portion of the first conductive layer 405a, which functions as one of the source and drain electrodes, and an end portion of the first conductive layer 405b which functions as the other of the source and drain electrodes. Accordingly, on-state characteristics (e.g., on-state current or field-effect mobility) of the transistor can be increased, enabling high-speed response and high-speed driving of the semiconductor device.

Through the above-described process, the transistor 420 of this embodiment is manufactured (see FIG. 2E). The transistor in which the oxide semiconductor layer 403 containing at least indium, zinc, and oxygen is used, the gate electrode is overlapped with the source and drain electrodes, and the coverage is good can be provided. Accordingly, a highly reliable structure for high-speed response and high-speed driving of a semiconductor device, in which on-state characteristics of a transistor are increased can be provided.

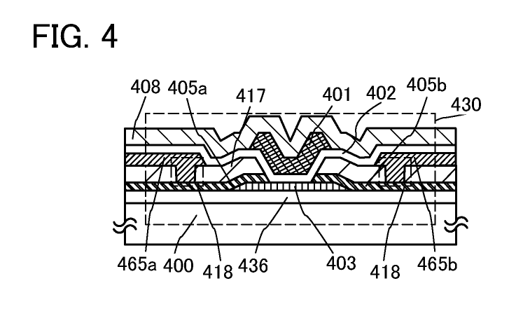

A modified example of the transistor 420 shown in FIG. 1 is described using FIG. 4. Repetitive description on portions which are the same as or have functions which are the same as those in portions in FIG. 1 is skipped in the following description of FIG. 4. In addition, detailed description of the same portions is skipped.

A structure of a transistor shown in FIG. 4 is different from that of the transistor shown in FIG. 1 in which the second conductive layer is directly stacked over the first conductive layer, and is a structure in which an insulating layer is provided between a first conductive layer and a second conductive layer.

FIG. 4 is a cross-sectional diagram of a transistor 430 which is an example which is different from the structure of the transistor 420 shown in FIG. 1.

The transistor 430 includes, over a substrate 400 having an insulating surface, a buffer layer 436, an oxide semiconductor layer 403, first conductive layers 405a and 405b, second conductive layers 465a and 465b, an insulating layer 417, a gate insulating layer 402, a gate electrode layer 401, and an interlayer insulating layer 408 (see FIG. 4).

In the structure shown in FIG. 4, like the structure shown in FIG. 1, the first conductive layers 405a and 405b, which function as a source and drain electrodes of the transistor 430, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 4, like the structure shown in FIG. 1, the second conductive layers 465a and 465b, which function as a source and drain electrodes of the transistor 430, are not overlapped with the gate electrode layer 401 with the gate insulating layer 402 provided therebetween in respective regions of the second conductive layers 465a and 465b which are overlapped with the oxide semiconductor layer 403.

Accordingly, in the structure shown in FIG. 4, the source electrode and the drain electrode of the transistor can be overlapped with a gate electrode without decreasing the source-drain current of the transistor, whereby on-state characteristics can be increased. Further, in the structure shown in FIG. 4, the coverage failure with the gate insulating layer can be decreased, which enables the oxide semiconductor layer and the gate insulating layer to be thin.

Further, in particular, in the structure shown in FIG. 4, the insulating layer 417 is provided between the first conductive layers 405a and 405b and the second conductive layers 465a and 465b, and the first conductive layer 405a, 405b is directly connected to the second conductive layer 465a, 465b in an opening 418. According to the structure, the first conductive layer and the second conductive layer can be processed into an appropriate shape even if the etching selectivity of the second conductive layer relative to the first conductive layer is low in manufacturing the transistor 430. Therefore, the same material can be used for the first conductive layer and the second conductive layer.

As described above, in the structure described in this embodiment, the source electrode and the drain electrode of the transistor can be overlapped with the gate electrode without decreasing the source-drain current of the transistor, whereby on-state characteristics can be increased. Further, in the structure described in this embodiment, the coverage failure with the gate insulating layer can be decreased, which enables the oxide semiconductor layer and the gate insulating layer to be thin. In that case, the transistor in which an oxide semiconductor is used for a channel formation region can be miniaturized, which is preferable.

This embodiment can be implemented combining with another embodiment as appropriate.

### Embodiment 2

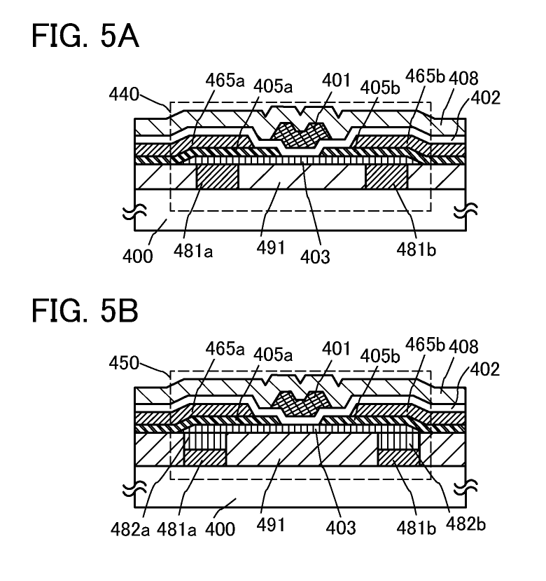

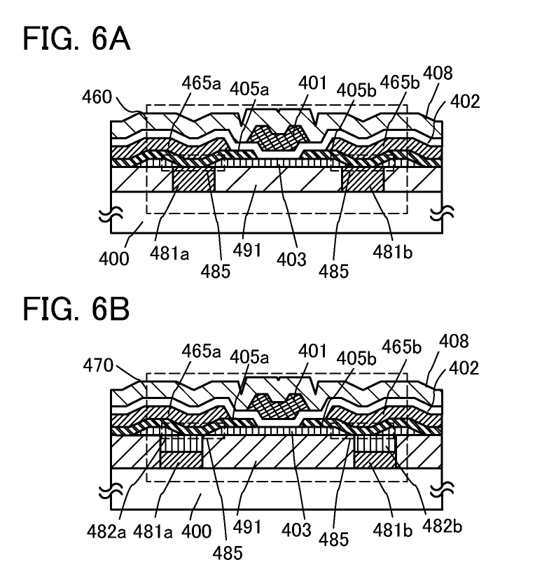

In this embodiment, another embodiment of the semiconductor device is described using FIGS. 5A and 5B and FIGS. 6A and 6B. The description of the above-described embodiment can apply to portions or steps which are the same as or have functions which are the same as those in the above-described embodiment, and repetitive description thereof is skipped. In addition, detailed description of the same portions is skipped.

FIG. 5A is a cross-sectional diagram of a transistor 440 which is an example which is different from the structure of the semiconductor device described in Embodiment 1.

The transistor 440 includes, over a substrate 400 having an insulating surface, an insulating layer 491 provided with embedded conductive layers 481a and 481b, an oxide semiconductor layer 403, first conductive layers 405a and 405b, second conductive layers 465a and 465b, a gate insulating layer 402, a gate electrode layer 401, and an interlayer insulating layer 408 (see FIG. 5A).

In the structure shown in FIG. 5A, like the structure shown in FIG. 1, the first conductive layers 405a and 405b, which function as a source and drain electrodes of the transistor 440, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 5A, like the structure shown in FIG. 1, the second conductive layers 465a and 465b, which function as a source and drain electrodes of the transistor 440, are not overlapped with the gate electrode layer 401 with the gate insulating layer 402 provided therebetween, in respective regions of the second conductive layers 465a and 465b which are overlapped with the oxide semiconductor layer 403.

Accordingly, in the structure shown in FIG. 5A, the source electrode and the drain electrode of the transistor can be overlapped with a gate electrode without decreasing the source-drain current of the transistor, whereby on-state characteristics can be increased. Further, in the structure shown in FIG. 5A, the coverage failure with the gate insulating layer can be decreased, which enables the oxide semiconductor layer and the gate insulating layer to be thin.

Further, in particular, in the structure shown in FIG. 5A described in this embodiment, the insulating layer 491 provided with the embedded conductive layers 481a and 481b is provided under the transistor 440 such that the embedded conductive layer 481a, 481b is overlapped with the first conductive layer 405a, 405b and the second conductive layer 465a, 465b with the oxide semiconductor layer 403 provided therebetween. The structure in which the embedded conductive layers 481a and 481b are provided under the transistor 440 enables connection to another transistor and/or an external control circuit without providing an opening in the gate insulating layer 402 and the interlayer insulating layer 408. The embedded conductive layer 481a, 481b can be in contact with the transistor 440 in a large area, whereby contact resistance can be decreased.

The embedded conductive layers 481a and 481b may be formed by the following: an embedded conductive layer is provided in each opening formed in the insulating layer 491 to fill the opening, and the surface is polished by a CMP method.

As the embedded conductive layers 481a and 481b, for example, a metal film containing an element selected from Al, Cr, Cu, Ta, Ti, Mo, and W, a metal nitride film containing any of the above elements as its component (e.g., a titanium nitride film, a molybdenum nitride film, or a tungsten nitride film), or the like can be used.

In the case where a metal film of Al, Cu, or the like is used for the embedded conductive layers 481a and 481b, it is preferable that a film of a high-melting-point metal such as Ti, Mo, or W or a metal nitride film thereof (e.g., a titanium nitride film, a molybdenum nitride film, or a tungsten nitride film) be stacked over or/and below the metal film.

Further, the embedded conductive layers 481a and 481b may also be formed using a conductive metal oxide. As the conductive metal oxide, indium oxide (In₂O₃), tin oxide (SnO₂), zinc oxide (ZnO), indium oxide-tin oxide (In₂O₃—SnO₂; abbreviated to ITO), indium oxide-zinc oxide (In₂O₃—ZnO), or any of these metal oxide materials to which silicon oxide is added can be used.

The insulating layer 491 can be formed by a CVD method, a sputtering method, or the like. The insulating layer 491 is preferably formed so as to include a silicon oxide, a silicon nitride, a silicon oxynitride, a silicon nitride oxide, an aluminum oxide, a hafnium oxide, a tantalum oxide, or the like. The insulating layer 491 has either a single-layer structure or a stacked-layer structure.

FIG. 5B is a cross-sectional diagram of a transistor 450 whose structure is different from that shown in FIG. 5A.

The transistor 450 includes, over a substrate 400 having an insulating surface, an insulating layer 491 provided with embedded conductive layers 481a and 481b and embedded oxide semiconductor layers 482a and 482b, an oxide semiconductor layer 403, first conductive layers 405a and 405b, second conductive layers 465a and 465b, a gate insulating layer 402, a gate electrode layer 401, and an interlayer insulating layer 408 (see FIG. 5B).

In the structure shown in FIG. 5B, like the structure shown in FIG. 1, the first conductive layers 405a and 405b, which function as a source and drain electrodes of the transistor 450, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 5B, like the structure shown in FIG. 1, the second conductive layers 465a and 465b, which function as a source and drain electrodes of the transistor 450, are not overlapped with the gate electrode layer 401 with the gate insulating layer 402 provided therebetween, in respective regions of the second conductive layers 465a and 465b which are overlapped with the oxide semiconductor layer 403.

Accordingly, in the structure shown in FIG. 5B, the source electrode and the drain electrode of the transistor can be overlapped with a gate electrode without decreasing the source-drain current of the transistor, whereby on-state characteristics can be increased. Further, in the structure shown in FIG. 5B, the coverage failure with the gate insulating layer can be decreased, which enables the oxide semiconductor layer and the gate insulating layer to be thin.

Further, in particular, in the structure shown in FIG. 5B described in this embodiment, the insulating layer 491 provided with the embedded conductive layers 481a and 481b and the embedded oxide semiconductor layers 482a and 482b is provided under the transistor 450 such that the embedded conductive layer 481a, 481b and embedded oxide semiconductor layer 482a, 482b are overlapped with the first conductive layer 405a, 405b and the second conductive layer 465a, 465b with the oxide semiconductor layer 403 provided therebetween. The structure in which the embedded conductive layers 481a and 481b are provided under the transistor 450 enables connection to another transistor and/or an external control circuit without providing an opening in the gate insulating layer 402 and the interlayer insulating layer 408. Further, the structure in which the embedded oxide semiconductor layer 482a, 482b is provided between the transistor 450 and the embedded conductive layer 481a, 481b enables good connection between the embedded conductive layer 481a, 481b and the transistor 450. The embedded conductive layer 481a, 481b can be in contact with the transistor 450 in a large area, and the embedded oxide semiconductor layer 482a, 482b enables good connection to the transistor 450, whereby contact resistance can be decreased.

The embedded oxide semiconductor layers 482a and 482b preferably contain at least indium (In) or zinc (Zn). In particular, In and Zn are preferably contained. As a stabilizer for reducing variation in electrical characteristics of the transistor using the oxide semiconductor, gallium (Ga) is preferably added thereto. Tin (Sn) is preferably contained as a stabilizer. Hafnium (Hf) is preferably contained as a stabilizer. Aluminum (Al) is preferably contained as a stabilizer. Zirconium (Zr) is preferably contained as a stabilizer.

The embedded oxide semiconductor layers 482a and 482b may also be formed using a metal oxide which is an oxide semiconductor layer with electrical conductivity. As the conductive metal oxide, indium oxide (In₂O₃), tin oxide (SnO₂), zinc oxide (ZnO), indium oxide-tin oxide (In₂O₃—SnO₂; abbreviated to ITO), indium oxide-zinc oxide (In₂O₃—ZnO), or any of these metal oxide materials to which silicon oxide is added can be used.

FIG. 6A is a cross-sectional diagram of a transistor 460 which is an example which is different from the structure of the semiconductor device shown in FIG. 5A.

The transistor 460 includes, over a substrate 400 having an insulating surface, an insulating layer 491 provided with embedded conductive layers 481a and 481b, an oxide semiconductor layer 403, first conductive layers 405a and 405b, second conductive layers 465a and 465b, a gate insulating layer 402, a gate electrode layer 401, and an interlayer insulating layer 408 (see FIG. 6A).

In the structure shown in FIG. 6A, like the structure shown in FIG. 1, the first conductive layers 405a and 405b, which function as a source and drain electrodes of the transistor 460, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 6A, like the structure shown in FIG. 1, the second conductive layers 465a and 465b, which function as a source and drain electrodes of the transistor 460, are not overlapped with the gate electrode layer 401 with the gate insulating layer 402 provided therebetween, in respective regions of the second conductive layers 465a and 465b which are overlapped with the oxide semiconductor layer 403.

Accordingly, in the structure shown in FIG. 6A, the source electrode and the drain electrode of the transistor can be overlapped with a gate electrode without decreasing the source-drain current of the transistor, whereby on-state characteristics can be increased. Further, in the structure shown in FIG. 6A, the coverage failure with the gate insulating layer can be decreased, which enables the oxide semiconductor layer and the gate insulating layer to be thin.

Further, in particular, in the structure shown in FIG. 6A described in this embodiment, like the structure shown in FIG. 5A, the insulating layer 491 provided with the embedded conductive layers 481a and 481b is provided under the transistor 460 such that the embedded conductive layer 481a, 481b is overlapped with the first conductive layer 405a, 405b and the second conductive layer 465a, 465b with the oxide semiconductor layer 403 provided therebetween. The structure in which the embedded conductive layers 481a and 481b are provided under the transistor 460 enables connection to another transistor and/or an external control circuit without providing an opening in the gate insulating layer 402 and the interlayer insulating layer 408. The embedded conductive layer 481a, 481b can be in contact with the transistor 460 in a large area, whereby contact resistance can be decreased.

Further, in particular, in the structure shown in FIG. 6A described in this embodiment, an opening 485 is formed in the oxide semiconductor layer 403, in which the first conductive layer 405a, 405b is directly connected to the embedded conductive layer 481a, 481b. With the structure, the current which flows through the first conductive layer and the second conductive layer which each function as the source and drain electrodes of the transistor, and the embedded conductive layer can be increased.

FIG. 6B is a cross-sectional diagram of a transistor 470 whose structure is different from that shown in FIG. 6A.

The transistor 470 includes, over a substrate 400 having an insulating surface, an insulating layer 491 provided with embedded conductive layers 481a and 481b and embedded oxide semiconductor layers 482a and 482b, an oxide semiconductor layer 403, first conductive layers 405a and 405b, second conductive layers 465a and 465b, a gate insulating layer 402, a gate electrode layer 401, and an interlayer insulating layer 408 (see FIG. 6B).

In the structure shown in FIG. 6B, like the structure shown in FIG. 1, the first conductive layers 405a and 405b, which function as a source and drain electrodes of the transistor 470, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIG. 6B, like the structure shown in FIG. 1, the second conductive layers 465a and 465b, which function as a source and drain electrodes of the transistor 470, are not overlapped with the gate electrode layer 401 with the gate insulating layer 402 provided therebetween, in respective regions of the second conductive layers 465a and 465b which are overlapped with the oxide semiconductor layer 403.

Accordingly, in the structure shown in FIG. 6B, the source electrode and the drain electrode of the transistor can be overlapped with a gate electrode without decreasing the source-drain current of the transistor, whereby on-state characteristics can be increased. Further, in the structure shown in FIG. 6B, the coverage failure with the gate insulating layer can be decreased, which enables the oxide semiconductor layer and the gate insulating layer to be thin.

Further, in particular, in the structure shown in FIG. 6B described in this embodiment, the insulating layer 491 provided with the embedded conductive layers 481a and 481b and the embedded oxide semiconductor layers 482a and 482b is provided under the transistor 470 such that the embedded conductive layer 481a, 481b and the embedded oxide semiconductor layer 482a, 482b are overlapped with the first conductive layer 405a, 405b and the second conductive layer 465a, 465b with the oxide semiconductor layer 403 provided therebetween. The structure in which the embedded conductive layers 481a and 481b are provided under the transistor 470 enables connection to another transistor and/or an external control circuit without providing an opening in the gate insulating layer 402 and the interlayer insulating layer 408. Further, the structure in which the embedded oxide semiconductor layer 482a, 482b is provided between the transistor 470 and the embedded conductive layer 481a, 481b enables good connection between the embedded conductive layer 481a, 481b and the transistor 470. The embedded conductive layer 481a, 481b can be in contact with the transistor 470 in a large area, and the embedded oxide semiconductor layer 482a, 482b enables good connection to the transistor 470, whereby contact resistance can be decreased.

Further, in particular, in the structure shown in FIG. 6B described in this embodiment, an opening 485 is formed in the oxide semiconductor layer 403, in which the first conductive layer 405a, 405b is directly connected to the embedded oxide semiconductor layer 482a, 482b. With the structure, the current which flows through the first conductive layer and the second conductive layer which each function as the source and drain electrodes of the transistor, the embedded oxide semiconductor layer, and the embedded conductive layer can be increased.

As described above, in the structure described in this embodiment, the source electrode and the drain electrode of the transistor can be overlapped with the gate electrode without decreasing the source-drain current of the transistor, whereby on-state characteristics can be increased. Further, in the structure described in this embodiment, the coverage failure with the gate insulating layer can be decreased, which enables the oxide semiconductor layer and the gate insulating layer to be thin. In that case, the transistor in which an oxide semiconductor is used for a channel formation region can be miniaturized, which is preferable. Further, in particular, in the structure described in this embodiment, the embedded conductive layer is provided, so that the contact resistance to the transistor can be decreased.

This embodiment can be implemented combining with another embodiment as appropriate.

### Embodiment 3

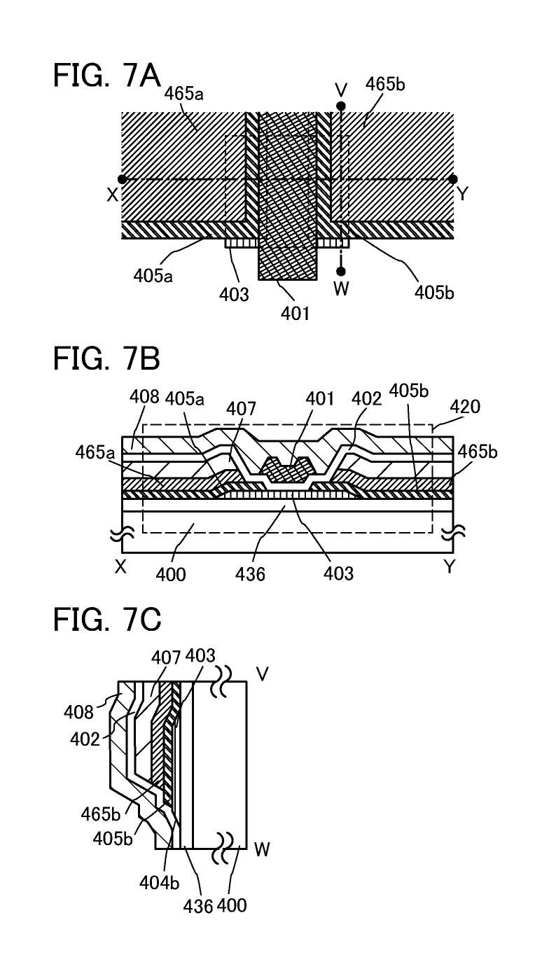

In this embodiment, another embodiment of the semiconductor device is described using FIGS. 7A to 7C. The description of the above-described embodiment can apply to portions or steps which are the same as or have functions which are the same as those in the above-described embodiment, and repetitive description thereof is skipped. In addition, detailed description of the same portions is skipped.

In this embodiment, FIG. 7A is a plane view of the transistor 420 shown in FIG. 1 described in Embodiment 1, FIG. 7B is a cross-sectional diagram along line X-Y in FIG. 7A, and FIG. 7C is a cross-sectional diagram along line V-W in FIG. 7A.

A structure of the transistor 420 shown in FIGS. 7A to 7C includes, like FIG. 1, over a substrate 400 having an insulating surface, a buffer layer 436, an oxide semiconductor layer 403, first conductive layers 405a and 405b, second conductive layers 465a and 465b, an insulating layer 407, a gate insulating layer 402, a gate electrode layer 401, and an interlayer insulating layer 408.

In the structure shown in FIGS. 7A to 7C described in this embodiment, like FIG. 1, the first conductive layers 405a and 405b, which function as a source and drain electrodes of the transistor 420, are overlapped with the gate electrode layer 401 with the gate insulating layer 402 provided therebetween, in respective regions of the first conductive layers 405a and 405b which are overlapped with the oxide semiconductor layer 403. In addition, in the structure shown in FIGS. 7A to 7C described in this embodiment, the second conductive layers 465a and 465b, which function as a source and drain electrodes of the transistor 420, are not overlapped with the gate electrode layer 401 with the gate insulating layer 402 provided therebetween, in respective regions of the second conductive layers 465a and 465b which are overlapped with the oxide semiconductor layer 403.

In the structure shown in FIGS. 7A to 7C described in this embodiment, respective end portions of the first conductive layers 405a and 405b, which function as the source and drain electrodes of the transistor, can be overlapped with an end portion of the gate electrode layer 401 which functions as a gate electrode of the transistor. Accordingly, on-state characteristics (e.g., on-state current or field-effect mobility) of the transistor can be increased, enabling high-speed response and high-speed driving of the semiconductor device.

Further, in the structure shown in FIGS. 7A to 7C described in this embodiment, the first conductive layers 405a and 405b, which function as the source and drain electrodes of the transistor, can be formed to be thin. By forming the first conductive layers 405a and 405b to be thin, the level of a step in the surface on which the gate insulating layer 402 is formed particularly in the vicinity of a channel formation region of the oxide semiconductor layer 403 can be low. Accordingly, the gate insulating layer 402 can be formed with good coverage. Reduction in coverage failure leads to reduction in occurrence of a short circuit between electrodes, increasing the reliability.

The thickness of the first conductive layer 405 over the oxide semiconductor layer 403 can be made uniform by forming the first conductive layers 405a and 405b to be thin. Also, by forming the first conductive layer 405 to be thin, the time taken to process for forming the first conductive layers 405a and 405b by a process such as an etching treatment can be shortened. Accordingly, damage to the oxide semiconductor layer 403 in processing the first conductive layers 405a and 405b can be reduced. Accordingly, the reliability can be increased.

Further, in the structure shown in FIGS. 7A to 7C described in this embodiment, not only the gate insulating layer 402 but also the oxide semiconductor layer 403 can be thinned. Reduction in the thicknesses of the gate insulating layer 402 and the oxide semiconductor layer 403 not only leads to an increase in on-state characteristics but also enables the transistor to operate as a fully-depleted transistor. Such an operation of the transistor as the fully-depleted transistor enables high integration, high-speed driving, and low power consumption.

In addition, in the structure shown in FIGS. 7A to 7C described in this embodiment, since the respective end portions of the second conductive layers 465a and 465b, which function as the source and drain electrodes of the transistor, can be prevented from being overlapped with the end portion of the gate electrode layer 401 which functions as the gate electrode, an increase in the thickness of the second conductive layers 465a and 465b as compared to the thickness of the first conductive layers 405a and 405b does not lead to generation of a short circuit between electrodes. Therefore, by increasing the thickness of the second conductive layers 465a and 465b, the source-drain current can be increased without causing a short circuit between electrodes.

Further, in the structure shown in FIGS. 7A to 7C described in this embodiment, the second conductive layers 465a and 465b and the insulating layer 407 are overlapped with each other and their side surfaces can be tapered by a process such as etching. Therefore, favorable coverage can be obtained even when the thickness of the second conductive layers 465a and 465b is increased.

As described above, in the structure shown in FIGS. 7A to 7C described in this embodiment, the source electrode and the drain electrode of the transistor can be overlapped with the gate electrode without decreasing the source-drain current of the transistor, whereby on-state characteristics can be increased. Further, in the structure shown in FIGS. 7A to 7C described in this embodiment, the coverage failure with the gate insulating layer can be decreased, which enables the oxide semiconductor layer and the gate insulating layer to be thin. In that case, the transistor in which an oxide semiconductor is used for a channel formation region can be miniaturized, which is preferable.

This embodiment can be implemented combining with another embodiment as appropriate.

### Embodiment 4

In this embodiment, an example of a semiconductor device which includes the transistor described in any of Embodiments 1 to 3, which can retain stored data even during a period in which power is not supplied, and which does not have a limitation on the number of write cycles, is described with reference to drawings. A transistor 162 included in the semiconductor device in this embodiment is the transistor described in any of Embodiments 1 to 3.

Since the off-state current of the transistor 162 is small, the transistor 162 enables stored data to be retained for a long time. In other words, a semiconductor memory device in which refresh operation is unnecessary or the frequency of refresh operation is extremely low can be provided, leading to a sufficient reduction in power consumption.

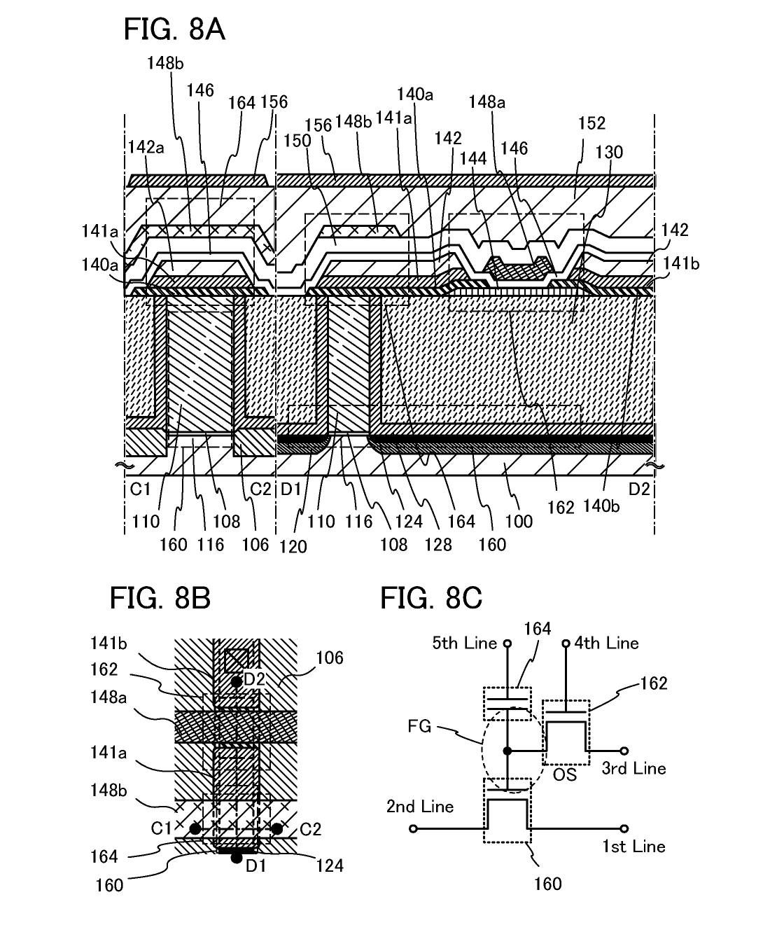

FIGS. 8A to 8C illustrate an example of a structure of a semiconductor device. FIG. 8A is a cross-sectional diagram of the semiconductor device, FIG. 8B is a plane view of the semiconductor device, and FIG. 8C is a circuit diagram of the semiconductor device. Here, FIG. 8A corresponds to a cross section along line C1-C2 and line D1-D2 in FIG. 8B.

The semiconductor device illustrated in FIGS. 8A and 8B includes a transistor 160 using a first semiconductor material in its lower portion, and a transistor 162 using a second semiconductor material in its upper portion. The transistor 162 can have the same structure as that described in any of Embodiments 1 to 3.

It is preferable that the first semiconductor material and the second semiconductor material be materials having different band gaps. For example, the first semiconductor material may be a semiconductor material other than an oxide semiconductor (e.g., silicon) and the second semiconductor material may be an oxide semiconductor. A transistor using a material other than an oxide semiconductor can operate at high speed easily. On the other hand, a transistor using an oxide semiconductor enables charge to be retained for a long time by virtue of its feature.

Although all the transistors are n-channel transistors in this embodiment, it is needless to say that a p-channel transistor(s) can alternatively be used. The technical nature of the disclosed invention is to use an oxide semiconductor for the transistor 162 in view of data retention; therefore, it is not necessary to limit a specific structure of the semiconductor device, such as materials of the semiconductor device or a structure of the semiconductor device, to the structure described here.

The transistor 160 in FIG. 8A includes a channel formation region 116 provided in a substrate 100 containing a semiconductor material (e.g., silicon), impurity regions 120 provided such that the channel formation region 116 is sandwiched therebetween, intermetallic compound regions 124 in contact with the impurity regions 120, a gate insulating layer 108 provided over the channel formation region 116, and a gate electrode layer 110 provided over the gate insulating layer 108.

An element isolation insulating layer 106 is provided over the substrate 100 so as to surround the transistor 160. An insulating layer 128 and an interlayer insulating layer 130 are provided so as to cover the transistor 160. In order to realize high integration, the transistor 160 preferably has a structure without a sidewall insulating layer as illustrated in FIG. 8A. On the other hand, when the characteristics of the transistor 160 have priority, a sidewall insulating layer may be formed on the side surface of the gate electrode layer 110 and the impurity regions 120 may include a region having a different impurity concentration.

The transistor 162 shown in FIG. 8A uses an oxide semiconductor for its channel formation region. It is preferable that an oxide semiconductor layer 144 included in the transistor 162 be highly purified. By using a highly purified oxide semiconductor, the transistor 162 can be provided with extremely superior off-state characteristics.

An insulating layer 150 having a single-layer structure or a stacked-layer structure is provided over the transistor 162. Further, a conductive layer 148b is provided in a region which overlaps with a first conductive layer 140a and a second conductive layer 141a which each function as an electrode layer of the transistor 162, with the insulating layer 150 provided therebetween, so that the first conductive layer 140a and the second conductive layer 141a, an insulating layer 142 and the insulating layer 150, and the conductive layer 148b form a capacitor 164. That is, the first conductive layer 140a and the second conductive layer 141a of the transistor 162 function as one electrode of the capacitor 164, and the conductive layer 148b functions as the other electrode of the capacitor 164. The capacitor 164 may be omitted if a capacitor is unnecessary. Alternatively, the capacitor 164 may be separately provided above the transistor 162.

An insulating layer 152 is provided over the transistor 162 and the capacitor 164. Further, a wiring 156 for connecting the transistor 162 to another transistor is provided over the insulating layer 152. Although not shown in FIG. 8A, the wiring 156 is connected to the second conductive layer 141a and a second conductive layer 141b via an electrode formed in an opening formed in the insulating layer 150, the insulating layer 152, a gate insulating layer 146, or the like.

The first conductive layer 140a and a first conductive layer 140b are, as described in Embodiment 1, overlapped with part of a conductive layer 148a which functions as a gate electrode of the transistor 162. The second conductive layer 141a and the second conductive layer 141b are, as described in Embodiment 1, not overlapped with part of the conductive layer 148a which functions as the gate electrode of the transistor 162. As a result, a source electrode and a drain electrode of the transistor can be overlapped with the gate electrode without decreasing the source-drain current of the transistor, whereby on-state characteristics can be increased. Further, the coverage failure with the gate insulating layer can be decreased, which enables the oxide semiconductor layer and the gate insulating layer to be thin. Accordingly, the transistor can be miniaturized.

In FIGS. 8A and 8B, the transistor 160 and the transistor 162 are overlapped with each other at least partly; it is preferable that a source region or a drain region of the transistor 160 overlap with part of the oxide semiconductor layer 144. Further, the transistor 162 and the capacitor 164 are provided so as to overlap with at least part of the transistor 160. For example, the first conductive layer 140a, which functions as one electrode of the capacitor 164, is provided so as to overlap with the gate electrode layer 110 of the transistor 160 at least partly. With such a planar layout, the area occupied by the semiconductor device can be reduced; thus, higher integration can be achieved.

Next, an example of a circuit configuration corresponding to FIGS. 8A and 8B is illustrated in FIG. 8C.

In FIG. 8C, a first wiring (1st Line) is connected to a source electrode of the transistor 160. A second wiring (2nd Line) is connected to a drain electrode of the transistor 160. A third wiring (3rd Line) is connected to one of a source electrode and a drain electrode of the transistor 162. A fourth wiring (4th Line) is connected to the gate electrode of the transistor 162. A gate electrode of the transistor 160 is connected to the other of the source electrode and the drain electrode of the transistor 162 and the one electrode of the capacitor 164. A fifth wiring (5th Line) is connected to the other electrode of the capacitor 164.

The semiconductor device illustrated in FIG. 8C can write, retain, and read data as described below, utilizing its feature in which the potential of the gate electrode of the transistor 160 can be retained.

Writing and retaining of data is described. First, the potential of the 4th Line is set to a potential at which the transistor 162 is turned on, so that the transistor 162 is turned on. Thus, the potential of the 3rd Line is supplied to the gate electrode of the transistor 160 and the one electrode of the capacitor 164. That is, predetermined charge is given to the gate electrode of the transistor 160 (writing). In this embodiment, one of two potential levels (H level and L level) is given thereto. After that, the potential of the 4th Line is set to a potential at which the transistor 162 is turned off, so that the transistor 162 is turned off. Thus, the potential supplied to the gate electrode of the transistor 160 is retained (retaining).

Since the off-state current of the transistor 162 is extremely small, the charge of the gate electrode of the transistor 160 is retained for a long time.

Next, reading of data is described. By supplying an appropriate potential (reading potential) to the 5th Line while supplying a predetermined potential (constant potential) to the 1st Line, the potential of the 2nd Line varies depending on the potential of the gate electrode of the transistor 160. This is because, when the transistor 160 is an n-channel transistor, an apparent threshold voltage Vₜₕ_{_{—}}_{H} in the case where the High level is given to the gate electrode of the transistor 160 is lower than an apparent threshold voltage Vₜₕ_{_{—}}_{L} in the case where the Low level is given to the gate electrode of the transistor 160. The apparent threshold voltage refers to a potential of the 5th Line, which is needed to turn on the transistor 160. Thus, the potential of the 5th Line is set to a potential V₀ between Vₜₕ_{_{—}}_{H} and Vₜₕ_{_{—}}_{L}, whereby charge given to the gate electrode of the transistor 160 can be determined. For example, in the case where the High level is given in data writing, the transistor 160 is turned on at the potential of the 5th Line of V₀ (>Vₜₕ_{_{—}}_{H}). On the other hand, in the case where the Low level is given in data writing, the transistor 160 remains in an off state at the potential of the 5th Line of V₀ (<Vₜₕ_{_{—}}_{L}). Therefore, the retained data can be read from the potential of the 2nd Line.

In the case where memory cells are arrayed, it is necessary that only data of a designated memory cell(s) can be read. Aside from such data reading, a potential at which the transistor 160 is turned off regardless of the state of the gate electrode of the transistor 160, that is, a potential lower than Vₜₕ_{_{—}}_{H} may be supplied to the 5th Line, or a potential at which the transistor 160 is turned on regardless of the state of the gate electrode of the transistor 160, that is, a potential higher than Vₜₕ_{_{—}}_{L} may be applied to the 5th Line.

The semiconductor device described in this embodiment can retain data for an extremely long period because the transistor in which a channel formation region is formed using an oxide semiconductor and whose off-state current is extremely small is applied thereto. That is, refresh operation is unnecessary or the frequency of refresh operation is extremely low, leading to a sufficient reduction in power consumption. Further, stored data can be retained for a long period even during a period in which power is not supplied (the potential is preferably fixed).

Further, in the semiconductor device described in this embodiment, high voltage is not needed for writing data and there is no problem of element deterioration. For example, unlike a conventional nonvolatile memory, it is not necessary to inject and extract electrons into/from a floating gate, and thus a problem such as deterioration of a gate insulating layer does not occur at all. In other words, the semiconductor device according to one embodiment of the present invention does not have a limit on the number of times of data writing, which is a problem in a conventional nonvolatile memory, and reliability thereof is drastically increased. Further, since data is written by turning the transistor on or off, high-speed operation can be easily realized.

This embodiment can be implemented combining with another embodiment as appropriate.

### Embodiment 5

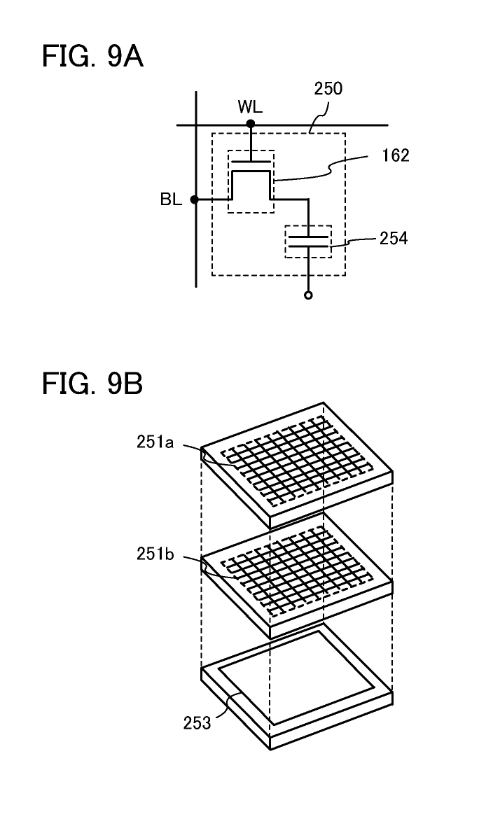

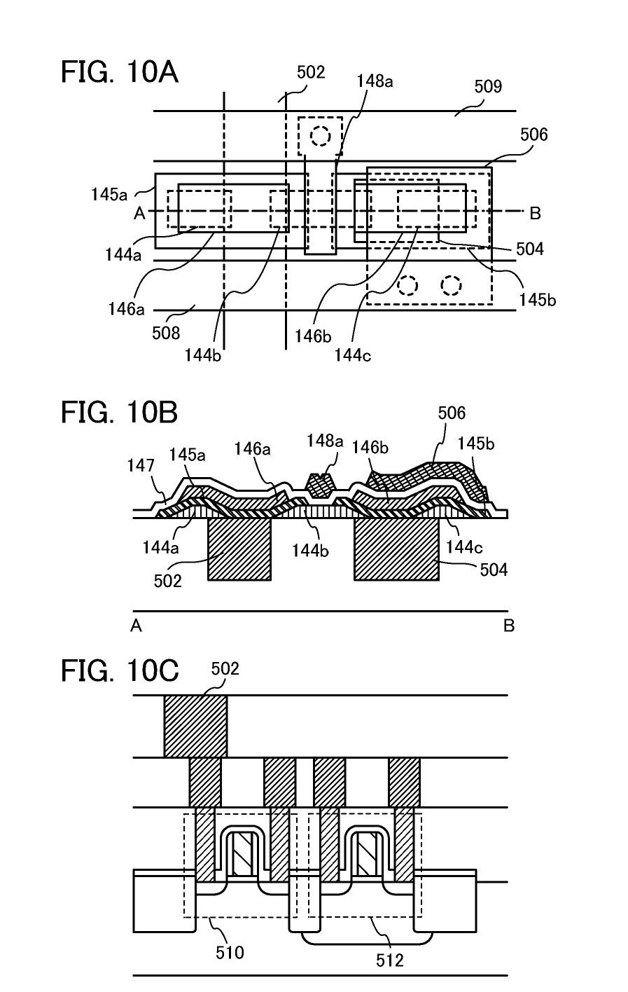

In this embodiment, a structure of a semiconductor device which includes the transistor described in any of Embodiments 1 to 3, which can retain stored data even during a period in which power is not supplied, and which does not have a limitation on the number of write cycles, is described with reference to FIGS. 9A and 9B and FIGS. 10A to 10C; the structure is different from that described in Embodiment 4. A transistor 162 included in the semiconductor device in this embodiment is the transistor described in any of Embodiments 1 to 3.

FIG. 9A illustrates an example of a circuit configuration of a semiconductor device, and FIG. 9B is a conceptual diagram illustrating an example of a semiconductor device. First, the semiconductor device illustrated in FIG. 9A is described, and then, the semiconductor device illustrated in FIG. 9B is described.

In the semiconductor device illustrated in FIG. 9A, a bit line BL is connected to one of a source electrode and a drain electrode of the transistor 162. A word line WL is connected to a gate electrode of the transistor 162. The other electrode of the source electrode and the drain electrode of the transistor 162 is connected to one electrode of a capacitor 254.

The transistor 162 using an oxide semiconductor has a feature of an extremely small off-state current. For that reason, the potential of one electrode of the capacitor 254 (or charge accumulated in the capacitor 254) can be retained for an extremely long time by turning off the transistor 162.

Next, writing and retaining of data in the semiconductor device (a memory cell 250) illustrated in FIG. 9A is described.

First, the potential of the word line WL is set to a potential at which the transistor 162 is turned on, so that the transistor 162 is turned on. Accordingly, the potential of the bit line BL is supplied to the one electrode of the capacitor 254 (writing). After that, the potential of the word line WL is set to a potential at which the transistor 162 is turned off, so that the transistor 162 is turned off. Accordingly, the potential of the one electrode of the capacitor 254 is retained (retaining).

Since the off-state current of the transistor 162 is extremely small, the potential of the one electrode of the capacitor 254 (or the charge accumulated in the capacitor) can be retained for a long time.

Next, reading of data is described. The transistor 162 is turned on, so that the bit line BL being in a floating state is electrically connected to the one electrode of the capacitor 254, and the charge is redistributed between the bit line BL and the one electrode of the capacitor 254. As a result, the potential of the bit line BL is changed. The amount of change in potential of the bit line BL varies depending on the potential of the one electrode of the capacitor 254 (or the charge accumulated in the capacitor 254).

For example, where V is the potential of the one electrode of the capacitor 254, C is the capacitance of the capacitor 254, CB is the capacitance of the bit line BL (hereinafter also referred to as bit line capacitance), and VB0 is the potential of the bit line BL before the charge redistribution, the potential of the bit line BL after charge redistribution is (CB×VB0+C×V)/(CB+C). Therefore, it can be found that assuming that the memory cell 250 takes either of two states in which the potentials of the one electrode of the capacitor 254 are V1 and V0 (V1>V0), the potential of the bit line BL at the potential V1 (=(CB×VB0+C×V1)/(CB+C)) is higher than the potential of the bit line BL at the potential V0 (=(CB×VB0+C×V0)/(CB+C)).

Then, the potential of the bit line BL is compared with a predetermined potential, whereby data can be read.

As described above, the semiconductor device illustrated in FIG. 9A can retain charge that is accumulated in the capacitor 254 for a long time in virtue of extremely small off-state current of the transistor 162. That is, refresh operation is unnecessary or the frequency of refresh operation is extremely low, leading to a sufficient reduction in power consumption. Further, stored data can be retained for a long period even during a period in which power is not supplied.

Next, the semiconductor device illustrated in FIG. 9B is described.

The semiconductor device illustrated in FIG. 9B includes memory cell arrays 251a and 251b each including the plurality of memory cells 250 illustrated in FIG. 9A as a memory circuit in its upper portion, and includes a peripheral circuit 253 for driving the memory cell arrays 251a and 251b in its lower portion. The peripheral circuit 253 is connected to a memory cell array 251 (the memory cell arrays 251a and 251b).

According to the structure illustrated in FIG. 9B, the peripheral circuit 253 can be provided directly under the memory cell array 251, which enables the semiconductor device to be downsized.

It is preferable that a semiconductor material of a transistor provided in the peripheral circuit 253 be different from that of the transistor 162. For example, silicon, germanium, silicon germanium, silicon carbide, gallium arsenide, or the like can be used; a single crystal semiconductor is preferably used. Alternatively, an organic semiconductor material or the like may be used. A transistor using such a semiconductor material can operate at sufficiently high speed. Therefore, with the transistor, a variety of circuits (e.g., a logic circuit or a driver circuit) which need to operate at high speed can be favorably realized.

FIG. 9B illustrates, as an example, the semiconductor device in which two memory cell arrays (the memory cell arrays 251a and 251b) are stacked; however, the number of memory cell arrays to be stacked is not limited thereto. Three or more memory cell arrays may be stacked.

Next, a specific structure of the memory cell 250 illustrated in FIG. 9A is described with reference to FIGS. 10A to 10C.

FIGS. 10A to 10C illustrate an example of a structure of the memory cell 250. FIG. 10A is a plane view of the memory cell 250, and FIG. 10B is a cross-sectional diagram along line A-B in FIG. 10A.

A transistor 162 in FIGS. 10A and 10B can have the same structure as the transistor in any of Embodiments 1 to 3.

As illustrated in FIG. 10B, the transistor 162 is provided over an embedded conductive layer 502 and an embedded conductive layer 504. The embedded conductive layer 502 functions as a bit line BL in FIG. 10A and is in contact with a first conductive layer 145a of the transistor 162. The embedded conductive layer 504 functions as one electrode of a capacitor 254 in FIG. 10A and is in contact with a first conductive layer 145b of the transistor 162. Further, a second conductive layer 146a is provided over and in contact with the first conductive layer 145a of the transistor 162. A second conductive layer 146b is provided over and in contact with the first conductive layer 145b of the transistor 162. Over the transistor 162, the second conductive layer 146b functions as one electrode of a capacitor 254. Over the transistor 162, a conductive layer 506 in a region overlapped with the second conductive layer 146b functions as the other electrode of the capacitor 254.

As illustrated in FIG. 10A, the other conductive layer 506 of the capacitor 254 is connected to a capacitor line 508. A conductive layer 148a which functions as a gate electrode and is provided over an oxide semiconductor layer 144 with a gate insulating layer 147 provided therebetween is connected to a word line 509.

FIG. 10C is a cross-sectional diagram in a connection portion between a memory cell array 251 and a peripheral circuit. For example, a structure including an n-channel transistor 510 and a p-channel transistor 512 can be employed for the peripheral circuit. The n-channel transistor 510 and the p-channel transistor 512 are preferably formed using a semiconductor material other than an oxide semiconductor (e.g., silicon). With such a material, the transistor included in the peripheral circuit can operate at high speed.

Adoption of the planar layout illustrated in FIG. 10A enables the area occupied by the semiconductor device to be reduced, whereby the degree of integration can be increased.

As described above, the plurality of memory cells formed in multiple layers in the upper portion each include a transistor using an oxide semiconductor. Since the off-state current of a transistor using a non-single-crystal oxide semiconductor containing at least indium, zinc, and oxygen is small, the transistor enables stored data to be retained for a long time. In other words, the frequency of refresh operation can be extremely lowered, which leads to a sufficient reduction in power consumption. Further, as illustrated in FIG. 10B, the capacitor 254 is formed by stacking the embedded conductive layer 504, the oxide semiconductor layer 144, the gate insulating layer 147, and the conductive layer 506.

In this manner, a peripheral circuit using a transistor using a material other than an oxide semiconductor and a memory circuit using a transistor using an oxide semiconductor can be provided in an all-in-one device, whereby a semiconductor device having novel characteristics can be provided. In addition, the peripheral circuit and the memory circuit can be stacked each other, whereby the degree of integration of the semiconductor device can be increased.

This embodiment can be implemented combining with another embodiment as appropriate.

### Embodiment 6

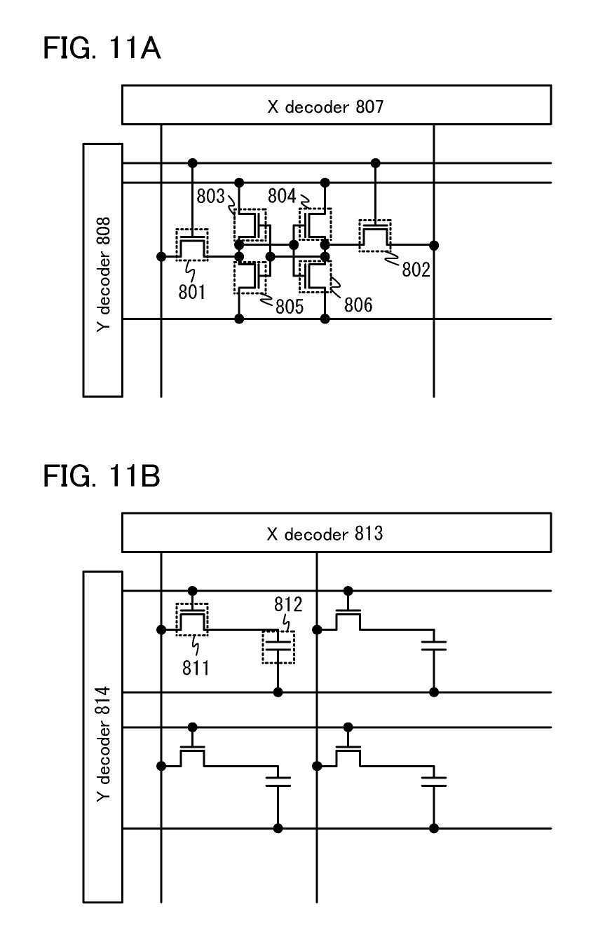

In this embodiment, examples of application of the semiconductor device described in any of the above embodiments to portable devices such as mobile phones, smartphones, or e-book readers are described with reference to FIGS. 11A and 11B and FIGS. 12 to 14.

In portable devices such as a mobile phone, a smartphone, and an e-book reader, an SRAM or a DRAM is used so as to store image data temporarily. This is because a flash memory whose response speed is low is not suitable for image processing. On the other hand, an SRAM or a DRAM has the following characteristics when used for temporary storage of image data.

In an ordinary SRAM, as illustrated in FIG. 11A, one memory cell includes 6 transistors, transistors 801 to 806, which is driven by an X decoder 807 and a Y decoder 808. The transistors 803 and 805 form an inverter, and the transistors 804 and 806 form an inverter, which enables high-speed driving. However, the SRAM has a drawback of large cell area because one memory cell includes 6 transistors. Provided that the minimum feature size of a design rule is F, the area of a memory cell in the SRAM is generally 100 F² to 150 F². Thus, the price per bit of the SRAM is the most expensive among a variety of memory devices.

On the other hand, as illustrated in FIG. 11B, a memory cell in a DRAM includes a transistor 811 and a storage capacitor 812, which is driven by an X decoder 813 and a Y decoder 814. One cell includes one transistor and one capacitor and thus the area of the memory cell is small. The area of a memory cell of the DRAM is generally less than or equal to 10 F². In the DRAM, a refresh operation is always necessary and accordingly power is consumed even when a rewriting operation is not performed.

However, the area of the memory cell of the semiconductor device described in the above embodiment is about 10 F² and frequent refreshing is not needed. Therefore, the area of the memory cell can be reduced, and the power consumption can be reduced.

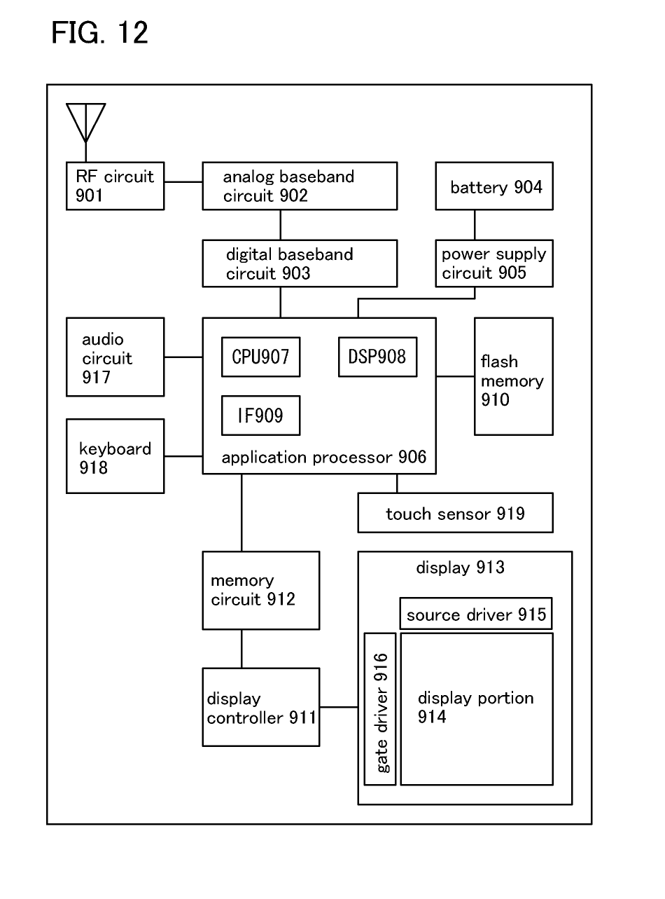

A block diagram of a portable device is illustrated in FIG. 12. The portable device illustrated in FIG. 12 includes an RF circuit 901, an analog baseband circuit 902, a digital baseband circuit 903, a battery 904, a power supply circuit 905, an application processor 906, a flash memory 910, a display controller 911, a memory circuit 912, a display 913, a touch sensor 919, an audio circuit 917, a keyboard 918, and the like. The display 913 includes a display portion 914, a source driver 915, and a gate driver 916. The application processor 906 includes a CPU 907, a DSP 908, and an interface 909. In general, the memory circuit 912 includes an SRAM or a DRAM; by employing the semiconductor device described in any of the above embodiments for the memory circuit 912, writing and reading of data can be performed at high speed, data can be retained for a long time, and power consumption can be sufficiently reduced.

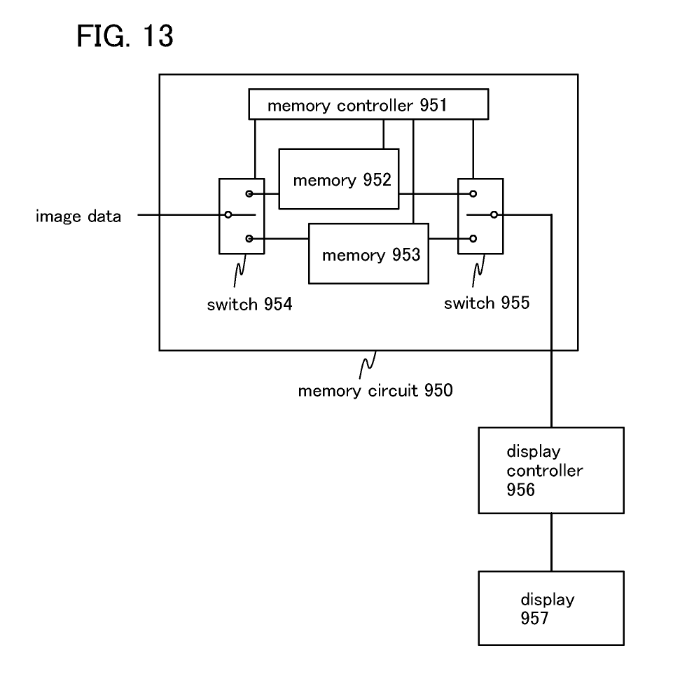

FIG. 13 illustrates an example of using the semiconductor device described in any of the above embodiments in a memory circuit 950 for a display. The memory circuit 950 illustrated in FIG. 13 includes a memory 952, a memory 953, a switch 954, a switch 955, and a memory controller 951. Further, the memory circuit is connected to a signal line through which image data (input image data) is transmitted, a display controller 956 which reads and controls data (stored image data) held in the memories 952 and 953, and a display 957 which performs image display by a signal from the display controller 956.

First, image data (input image data A) is formed by an application processor (not shown). The input image data A is stored in the memory 952 though the switch 954. The image data (stored image data A) stored in the memory 952 is transmitted to the display 957 through the switch 955 and the display controller 956 and displayed on the display 957.

In the case where the input image data A is not changed, the stored image data A is read from the display controller 956 through the memory 952 and the switch 955 with a frequency of 30 Hz to 60 Hz in general.

Next, for example, when data displayed on the screen is changed by a user (that is, in the case where the input image data A is changed), new image data (input image data B) is formed by the application processor. The input image data B is stored in the memory 953 through the switch 954. The stored image data A is read periodically from the memory 952 through the switch 955 even during that time. After completion of storing the new image data (the stored image data B) in the memory 953, from the next frame for the display 957, the stored image data B starts to be read, transmitted to the display 957 through the switch 955 and the display controller 956, and displayed on the display 957. This reading operation is continued until the next new image data is stored in the memory 952.

By alternately writing and reading image data to/from the memory 952 and the memory 953 as described above, images are displayed on the display 957. The memories 952 and 953 are not necessarily different memories; one memory may be divided into the memories 952 and 953. The semiconductor device described in any of the above embodiments, which can be applied to the memory 952 and the memory 953, enables data to be written and read at high speed and retained for a long time, and enables power consumption to be sufficiently reduced.

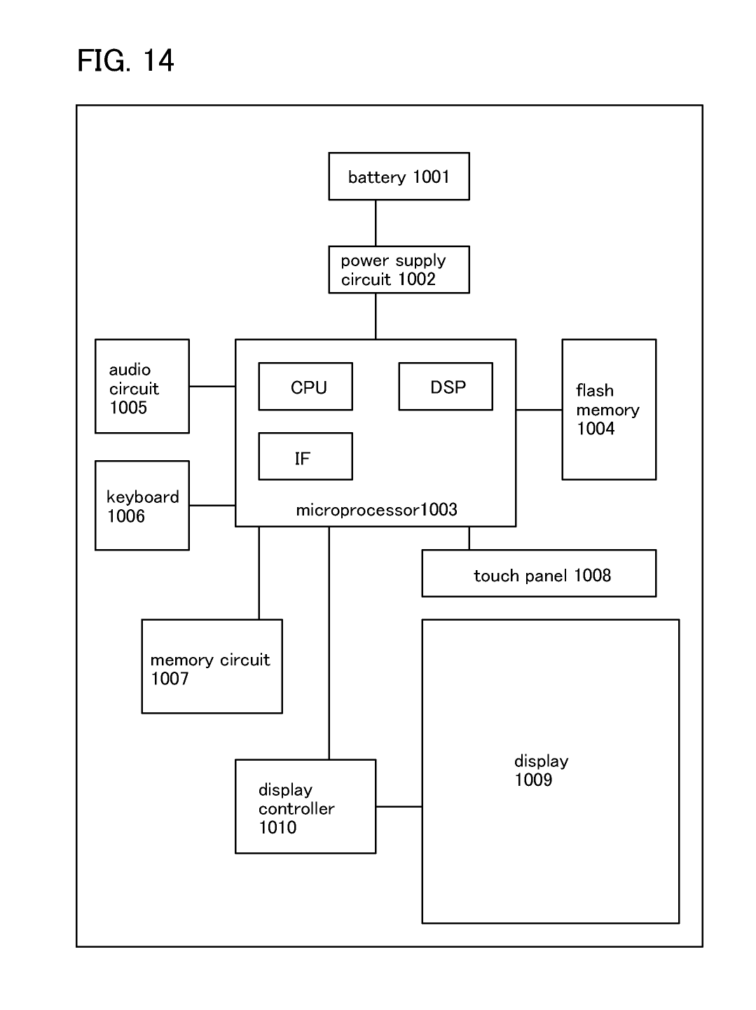

FIG. 14 is a block diagram of an e-book reader. The e-book reader illustrated in FIG. 14 includes a battery 1001, a power supply circuit 1002, a microprocessor 1003, a flash memory 1004, an audio circuit 1005, a keyboard 1006, a memory circuit 1007, a touch panel 1008, a display 1009, and a display controller 1010.

Here, the semiconductor device described in any of the above embodiments can be used for the memory circuit 1007 in FIG. 14. The memory circuit 1007 has a function of temporarily storing the contents of the book. For example, users use a highlight function in some cases. When users read an e-book reader, they sometimes want to mark a specified portion. This marking refers to a highlight function to make a difference from other portions by, for example, changing the color of the display, underlining the word, making the letter bold, or changing the font type of the letter. Then, data in the portion specified by the user is stored and retained. In order to save the data for a long time, the data may be copied into the flash memory 1004. Even in such a case, by employing the semiconductor device described in any of the above embodiments, writing and reading of data can be performed at high speed and retained for a long time, and power consumption can be sufficiently reduced.

As described above, the semiconductor device in any of the above embodiments is provided for each of the portable devices described in this embodiment. Accordingly, a portable device in which reading of data is performed at high speed and retained for a long time, and power consumption is sufficiently reduced, can be realized.

This embodiment can be implemented combining with another embodiment as appropriate.

### Embodiment 7

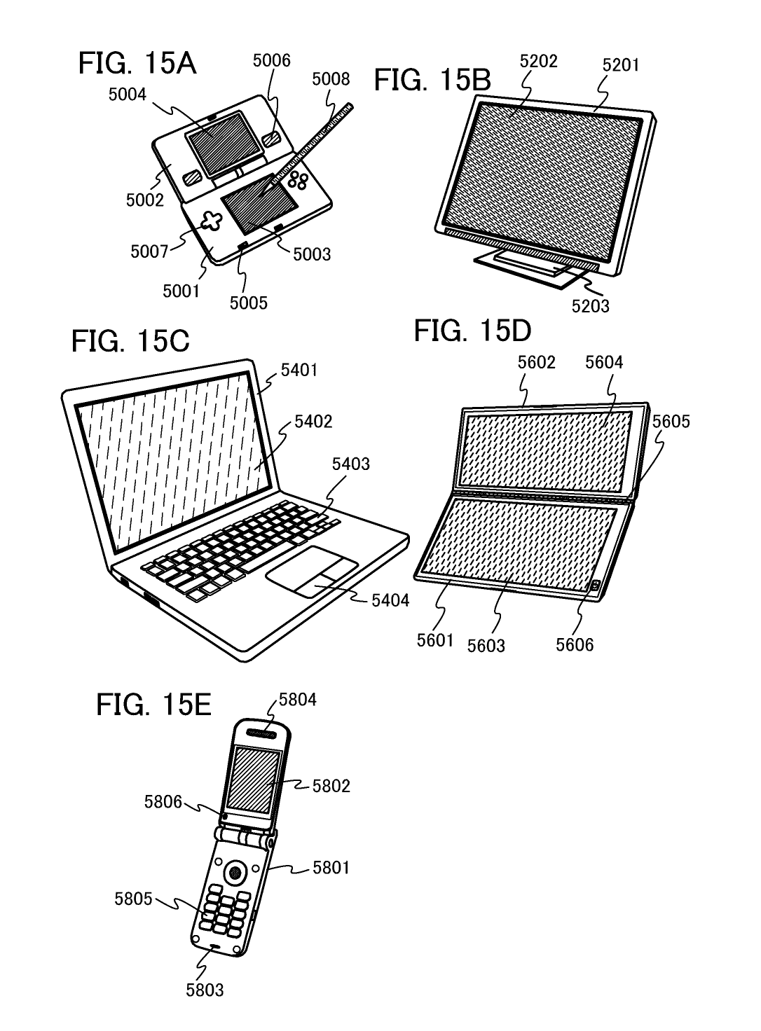

The semiconductor device according to one embodiment of the present invention can be used for display devices, personal computers, or image reproducing devices provided with recording media (typically, devices which reproduce the contents of recording media such as digital versatile discs (DVDs) and have displays for displaying the reproduced images). Other than the above, as examples of an electronic device which can use the semiconductor device according to one embodiment of the present invention, mobile phones, game machines including portable game machines, portable information terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), vending machines, and the like can be given. Specific examples of such electronic devices are illustrated in FIGS. 15A to 15E.

FIG. 15A illustrates a portable game console including a housing 5001, a housing 5002, a display portion 5003, a display portion 5004, a microphone 5005, a speaker 5006, an operation key 5007, a stylus 5008, and the like. The semiconductor device according to one embodiment of the present invention, which can be applied to a driver circuit of the portable game console, enables the operation speed of the portable game console to be high. Further or alternatively, application of the semiconductor device according to one embodiment of the present invention enables the size of the portable game console to be small. Although the portable game console illustrated in FIG. 15A has the two display portions 5003 and 5004, the number of display portions of the portable game console is not limited to two.

FIG. 15B illustrates a display device including a bezel 5201, a display portion 5202, a support base 5203, and the like. The semiconductor device according to one embodiment of the present invention, which can be applied to a driver circuit of the display device, enables the operation speed of the display device to be high. Further or alternatively, application of the semiconductor device according to one embodiment of the present invention enables the size of the display device to be small. The display device includes, in its category, any display device for displaying information, such as display devices for personal computers, TV broadcast reception, and advertisement.

FIG. 15C illustrates a laptop personal computer including a bezel 5401, a display portion 5402, a keyboard 5403, a pointing device 5404, and the like. The semiconductor device according to one embodiment of the present invention, which can be applied to a driver circuit of the laptop personal computer, enables the operation speed of the laptop personal computer to be high. Further or alternatively, application of the semiconductor device according to one embodiment of the present invention enables the size of the laptop personal computer to be small.

FIG. 15D illustrates a portable information terminal including a first housing 5601, a second housing 5602, a first display portion 5603, a second display portion 5604, a connection portion 5605, an operation key 5606, and the like. The first display portion 5603 is provided for the first housing 5601, and the second display portion 5604 is provided for the second housing 5602. The first housing 5601 is connected to the second housing 5602 by the connection portion 5605, and the angle between the first housing 5601 and the second housing 5602 can be changed by the connection portion 5605. The image displayed on the first display portion 5603 may be switched in accordance with the angle in the connection portion 5605 between the first housing 5601 and the second housing 5602. A semiconductor display device with a function as a position input device may be used for at least one of the first display portion 5603 and the second display portion 5604. The function as a position input device can be provided by providing a touch panel for the semiconductor display device. The function as a position input device can also be provided by providing a photoelectric converter which is also called a photosensor in a pixel portion of the semiconductor display device. The semiconductor device according to one embodiment of the present invention, which can be applied to a driver circuit of the portable information terminal, enables the operation speed of the portable information terminal to be high. Further or alternatively, application of the semiconductor device according to one embodiment of the present invention enables the size of the portable information terminal to be small.

FIG. 15E illustrates a mobile phone including a housing 5801, a display portion 5802, an audio input portion 5803, an audio output portion 5804, operation keys 5805, a light-receiving portion 5806, and the like. Light received in the light-receiving portion 5806 is converted into electrical signals, whereby external images can be loaded. The semiconductor device according to one embodiment of the present invention, which can be applied to a driver circuit of the mobile phone, enables the operation speed of the mobile phone to be high. Further or alternatively, application of the semiconductor device according to one embodiment of the present invention enables the size of the mobile phone to be small.

This embodiment can be implemented combining with another embodiment as appropriate.

### EXPLANATION OF REFERENCE

100: substrate; 106: element isolation insulating layer; 108: gate insulating layer; 110: gate electrode layer; 116: channel formation region; 120: impurity region; 124: intermetallic compound region; 128: insulating layer; 130: interlayer insulating layer; 140a: conductive layer; 140b: conductive layer; 141a: conductive layer; 141b: conductive layer; 142: insulating layer; 144: oxide semiconductor layer; 145a: conductive layer; 145b: conductive layer; 146: gate insulating layer; 148a: conductive layer; 148b: conductive layer; 150: insulating layer; 152: insulating layer; 153: conductive layer; 156: wiring; 160: transistor; 162: transistor; 164: capacitor; 250: memory cell; 251: memory cell array; 251a: memory cell array; 251b: memory cell array; 253: peripheral circuit; 254: capacitor; 400: substrate; 401: gate electrode layer; 402: gate insulating layer; 403: oxide semiconductor layer; 405: conductive layer; 405a: conductive layer; 405b: conductive layer; 407: insulating layer; 408: interlayer insulating layer; 417: insulating layer; 418: opening; 420: transistor; 430: transistor; 436: buffer layer; 440: transistor; 450: transistor; 460: transistor; 465: conductive layer; 465a: conductive layer; 465b: conductive layer; 470: transistor; 481a: embedded conductive layer; 481b: embedded conductive layer; 482a: oxide semiconductor layer; 482b: oxide semiconductor layer; 485: opening; 491: insulating layer; 502: embedded conductive layer; 504: embedded conductive layer; 506: conductive layer; 508: capacitor line; 509: word line; 510: n-channel transistor; 512: p-channel transistor; 801: transistor; 803: transistor; 804: transistor; 805: transistor; 806: transistor; 807: X decoder; 808: Y decoder; 811: transistor; 812: storage capacitor; 813: X decoder; 814: Y decoder; 901: RF circuit; 902: analog baseband circuit; 903: digital baseband circuit; 904: battery; 905: power supply circuit; 906: application processor; 907: CPU; 908: DSP; 909: interface; 910: flash memory; 911: display controller; 912: memory circuit; 913: display; 914: display portion; 915: source driver; 916: gate driver; 917: audio circuit; 918: keyboard; 919: touch sensor; 950: memory circuit; 951: memory controller; 952: memory; 953: memory; 954: switch; 955: switch; 956: display controller; 957: display; 1001: battery; 1002: power supply circuit; 1003: microprocessor; 1004: flash memory; 1005: audio circuit; 1006: keyboard; 1007: memory circuit; 1008: touch panel; 1009: display; 1010: display controller; 5001: housing; 5002: housing; 5003: display portion; 5004: display portion; 5005: microphone; 5006: speaker; 5007: operation key; 5008: stylus; 5201: bezel; 5202: display portion; 5203: support base; 5401: bezel; 5402: display portion; 5403: keyboard; 5404: pointing device; 5601: housing; 5602: housing; 5603: display portion; 5604: display portion; 5605: connection portion; 5606: operation key; 5801: housing; 5802: display portion; 5803: audio input portion; 5804: audio output portion; 5805: operation key; 5806: light-receiving portion

This application is based on Japanese Patent Application serial no. 2011-208232 filed with Japan Patent Office on Sep. 23, 2011, the entire contents of which are hereby incorporated by reference.

1. A semiconductor device comprising:
an oxide semiconductor layer provided over a substrate comprising an insulating surface;
a first conductive layer provided partly over the oxide semiconductor layer;
a second conductive layer provided partly over the first conductive layer;
a gate insulating layer provided over the oxide semiconductor layer, the first conductive layer, and the second conductive layer; and
a gate electrode layer provided over the oxide semiconductor layer with the gate insulating layer provided therebetween,
wherein the gate electrode layer is overlapped with the first conductive layer with the gate insulating layer provided therebetween, and is not overlapped with the second conductive layer with the gate insulating layer provided therebetween.

2. The semiconductor device according to claim 1, wherein a thickness of the first conductive layer is greater than or equal to 5 nm and less than or equal to 20 nm.

3. The semiconductor device according to claim 1, wherein a thickness of the gate insulating layer is greater than or equal to 10 nm and less than or equal to 20 nm.

4. The semiconductor device according to claim 1, wherein a thickness of the oxide semiconductor layer is greater than or equal to 5 nm and less than or equal to 20 nm.

5. The semiconductor device according to claim 1, wherein a buffer layer is provided over the substrate comprising the insulating surface.

6. The semiconductor device according to claim 5, wherein the buffer layer comprises an oxide of at least one element selected from the group consisting of aluminum, gallium, zirconium, hafnium, and a rare-earth element.

7. The semiconductor device according to claim 1, wherein the oxide semiconductor layer comprises crystals whose c-axes are aligned.

8. The semiconductor device according to claim 1, wherein the second conductive layer is provided partly over the oxide semiconductor layer.

9. A semiconductor device comprising:
an oxide semiconductor layer provided over a substrate comprising an insulating surface;
a first conductive layer provided partly over the oxide semiconductor layer;
a second conductive layer provided partly over the first conductive layer;
an insulating layer provided over the second conductive layer;
a gate insulating layer provided over the oxide semiconductor layer, the first conductive layer, the second conductive layer, and the insulating layer; and
a gate electrode layer provided over the oxide semiconductor layer with the gate insulating layer provided therebetween,
wherein the gate electrode layer is overlapped with the first conductive layer with the gate insulating layer provided therebetween, and is not overlapped with the second conductive layer with the gate insulating layer provided therebetween.

10. The semiconductor device according to claim 9, wherein a thickness of the first conductive layer is greater than or equal to 5 nm and less than or equal to 20 nm.

11. The semiconductor device according to claim 9, wherein a thickness of the gate insulating layer is greater than or equal to 10 nm and less than or equal to 20 nm.

12. The semiconductor device according to claim 9, wherein a thickness of the oxide semiconductor layer is greater than or equal to 5 nm and less than or equal to 20 nm.

13. The semiconductor device according to claim 9, wherein a buffer layer is provided over the substrate comprising the insulating surface.

14. The semiconductor device according to claim 13, wherein the buffer layer comprises an oxide of at least one element selected from the group consisting of aluminum, gallium, zirconium, hafnium, and a rare-earth element.

15. The semiconductor device according to claim 9, wherein the oxide semiconductor layer comprises crystals whose c-axes are aligned.

16. A semiconductor device comprising:
an oxide semiconductor layer provided over a substrate comprising an insulating surface;
a first conductive layer provided partly over the oxide semiconductor layer;
an insulating layer provided partly over the first conductive layer;
a second conductive layer provided partly over the insulating layer and is in contact with the first conductive layer in an opening in the insulating layer;
a gate insulating layer provided over the oxide semiconductor layer, the first conductive layer, the second conductive layer, and the insulating layer; and
a gate electrode layer provided over the oxide semiconductor layer with the gate insulating layer provided therebetween,
wherein the gate electrode layer is overlapped with the first conductive layer with the gate insulating layer provided therebetween, and is not overlapped with the second conductive layer with the gate insulating layer provided therebetween.

17. The semiconductor device according to claim 16, wherein a thickness of the first conductive layer is greater than or equal to 5 nm and less than or equal to 20 nm.

18. The semiconductor device according to claim 16, wherein a thickness of the gate insulating layer is greater than or equal to 10 nm and less than or equal to 20 nm.

19. The semiconductor device according to claim 16, wherein a thickness of the oxide semiconductor layer is greater than or equal to 5 nm and less than or equal to 20 nm.

20. The semiconductor device according to claim 16, wherein a buffer layer is provided over the substrate comprising the insulating surface.

21. The semiconductor device according to claim 20, wherein the buffer layer comprises an oxide of at least one element selected from the group consisting of aluminum, gallium, zirconium, hafnium, and a rare-earth element.

22. The semiconductor device according to claim 16, wherein the oxide semiconductor layer comprises crystals whose c-axes are aligned.

23. A semiconductor device comprising:
a substrate comprising an insulating surface;
an insulating layer partly comprising an embedded conductive layer over the insulating surface;
an oxide semiconductor layer over the insulating layer;
a first conductive layer provided partly over the oxide semiconductor layer;
a second conductive layer provided partly over the first conductive layer;
a gate insulating layer provided over the oxide semiconductor layer, the first conductive layer, and the second conductive layer; and
a gate electrode layer provided over the oxide semiconductor layer with the gate insulating layer provided therebetween,
wherein the gate electrode layer is overlapped with the first conductive layer with the gate insulating layer provided therebetween, and is not overlapped with the second conductive layer with the gate insulating layer provided therebetween.

24. The semiconductor device according to claim 23, wherein the embedded conductive layer is in contact with the first conductive layer in an opening in the oxide semiconductor layer.

25. The semiconductor device according to claim 23, wherein the insulating layer partly comprising the embedded conductive layer comprises an embedded oxide semiconductor layer over the embedded conductive layer.

26. The semiconductor device according to claim 25, wherein the insulating layer partly comprising the embedded conductive layer and the embedded oxide semiconductor layer is provided such that the embedded oxide semiconductor layer is in contact with the first conductive layer in the opening in the oxide semiconductor layer in the semiconductor device.

27. The semiconductor device according to claim 23, wherein a thickness of the first conductive layer is greater than or equal to 5 nm and less than or equal to 20 nm.

28. The semiconductor device according to claim 23, wherein a thickness of the gate insulating layer is greater than or equal to 10 nm and less than or equal to 20 nm.

29. The semiconductor device according to claim 23, wherein a thickness of the oxide semiconductor layer is greater than or equal to 5 nm and less than or equal to 20 nm.

30. The semiconductor device according to claim 23, wherein a buffer layer is provided over the substrate comprising the insulating surface.

31. The semiconductor device according to claim 30, wherein the buffer layer comprises an oxide of at least one element selected from the group consisting of aluminum, gallium, zirconium, hafnium, and a rare-earth element.

32. The semiconductor device according to claim 23, wherein the oxide semiconductor layer comprises crystals whose c-axes are aligned.
